(19) United States
(12) Patent Application Publication
(10) Pub. No.: US 2026/0371680 A1
(43) Pub. Date: Nov. 19, 2026

(54) SEMICONDUCTOR DEVICE AND METHOD

(71) Applicant: Taiwan Semiconductor Manufacturing Co., Ltd., Hsinchu (TW)

(72) Inventors: Ta-Chun Lin, Hsinchu (TW); Jhon Jhy Liaw, Zhudong Township (TW)

(21) Appl. No.: 19/749,948

(22) Filed: Jul. 22, 2026

Related U.S. Application Data
(63) Continuation of application No. 18/811,479, filed on Aug. 21, 2024.

(51) Int. Cl. H10D 64/01; H10D 30/01; H10D 30/43; H10D 30/67; H10D 62/10

(52) U.S. Cl. CPC H10D 64/017; H10D 30/014; H10D 30/43; H10D 30/6735; H10D 30/6757; H10D 62/121

(57) ABSTRACT

A method includes depositing a multi-layer stack over a substrate, the multi-layer stack comprising a plurality of first sacrificial layers that alternate with a plurality of channel layers; forming a dummy gate structure over sidewalls and a top surface of the multi-layer stack, the dummy gate structure comprising a dummy gate over a dummy gate dielectric layer; forming spacers on sidewalls of the dummy gate and over the dummy gate dielectric layer; performing a first etching process to remove the dummy gate and a first portion of the dummy gate dielectric layer under the dummy gate to form a first recess, wherein after performing the first etching process, second portions of the dummy gate dielectric layer remain disposed under respective spacers; forming second recesses in respective ones of the second portions of the dummy gate dielectric layer; and forming a gate structure in the first recess and the second recesses.

### CROSS-REFERENCE TO RELATED APPLICATIONS

This application is a continuation of U.S. Patent Application No. 18/811,479, filed on Aug. 21, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nanostructure field-effect transistors (nano-FETs) in a three-dimensional view, in accordance with some embodiments.

FIGS. 2, 3, 4, 5, 6A, 6B, 6C, 7A, 7B, 7C, 8A, 8B, 8C, 9A, 9B, 9C, 10A, 10B, 10C, 11A, 11B, 11C, 11D, 12A, 12B, 12C, 13A, 13B, 13C, 14A, 14B, 14C, 15A, 15B, 15C, 16A, 16B, 16C, 17A, 17B, 17C, 17D, 17E, 17F, 17G, 17H, 18A, 18B, 18C, 19A, 19B, 19C, 20A, 20B, and 20C are views of intermediate processes in the manufacturing of a semiconductor device including nano-FETs, in accordance with some embodiments.

FIGS. 21, 22, 23A, 23B, and 23C are views of intermediate processes in the manufacturing of a semiconductor device including nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide semiconductor devices having improved performance and methods of forming the same. The semiconductor devices may be nanostructure field-effect transistors (nano-FETs, also referred to as nanosheet field-effect transistors (NSFETs), nanowire field-effect transistors (NWFETs), or gate-all-around field-effect transistors (GAAFETs)). These embodiments include methods applied to forming semiconductor nanostructures over a semiconductor fin, and forming a dummy gate stack and a mask over the semiconductor nanostructures and the fin. The dummy gate stack may comprise a dummy gate dielectric and a dummy gate over the dummy gate dielectric. Spacers are then formed on sidewalls of the dummy gate, and on the dummy gate dielectric. The dummy gate and a first portion of the dummy gate dielectric below the dummy gate are removed using a first etching process to form a first recess, wherein the first recess exposes a top surface of a topmost semiconductor nanostructure (e.g., which may form a topmost channel region of a subsequently formed nano-FET) of the semiconductor nanostructures. Subsequently, a second etching process is performed to remove a second portion of the dummy gate dielectric under each of the spacers, in order to form a second recess that extends laterally under the spacer, wherein the first recess and the second recess are connected. After the second etching process is performed, a third portion of the dummy gate dielectric remains under each of the spacers. A gate stack may then be formed, such that a first portion of the gate stack is disposed in the first recess and the second recess, wherein the gate stack comprises a gate dielectric layer and a gate electrode formed over the gate dielectric layer. In an embodiment, after the formation of the gate stack, the second recess is filled with the gate dielectric layer, such that the first portion of the gate stack is wider at its base (e.g., also referred to as the gate stack footing) which contacts the top surface of the topmost semiconductor nanostructure than other upper portions of the first portion of the gate stack. In an embodiment, after the formation of the gate stack, the second recess is filled with the gate dielectric layer and the gate electrode, such that the first portion of the gate stack is wider at its base (e.g., also referred to as the gate stack footing) which contacts the top surface of the topmost semiconductor nanostructure than other upper portions of the first portion of the gate stack.

Advantageous features of one or more embodiments disclosed herein may include the ability to modify the gate stack footing profile (e.g., by modifying a width of the gate stack footing) over the topmost channel region of the subsequently formed nano-FET to allow for improved control of the flow of electrical current through the topmost channel region. In addition, non-uniform doping profiles (e.g., as a result of using a dummy gate stack having a smaller width as an implantation mask) during subsequent ion implantation or doping processes can be minimized as a result of using the dummy gate stack having a wider gate stack footing profile. As a result, device performance is improved. In addition, a ratio of the width of the gate stack footing of the first portion of the gate stack to a width of a second portion of the gate stack (e.g., that is disposed between two adjacent channel regions of corresponding nano-FETs) can be tuned in order to optimize device performance and device drive currents. Further, because upper portions of the first portion of the gate stack can be formed having smaller widths than the width of the base (e.g., also referred to as the gate stack footing) of the first portion of the gate stack, the spacers that are disposed on sidewalls of the upper portions of the first portion of the gate stack may be formed to have larger widths, which increases electrical isolation between the first portion of the gate stack and adjacent epitaxial source/drain regions that are disposed on opposing sides of the first portion of the gate stack. This results in a reduced risk of shorting between the first portion of the gate stack and the adjacent epitaxial source/drain regions.

Some embodiments discussed herein are described in the context of a semiconductor device including nano-FETs. However, various embodiments may be applied to devices including other types of transistors (e.g., fin field effect transistors (FinFETs), planar transistors, or the like) in lieu of or in combination with the nano-FETs.

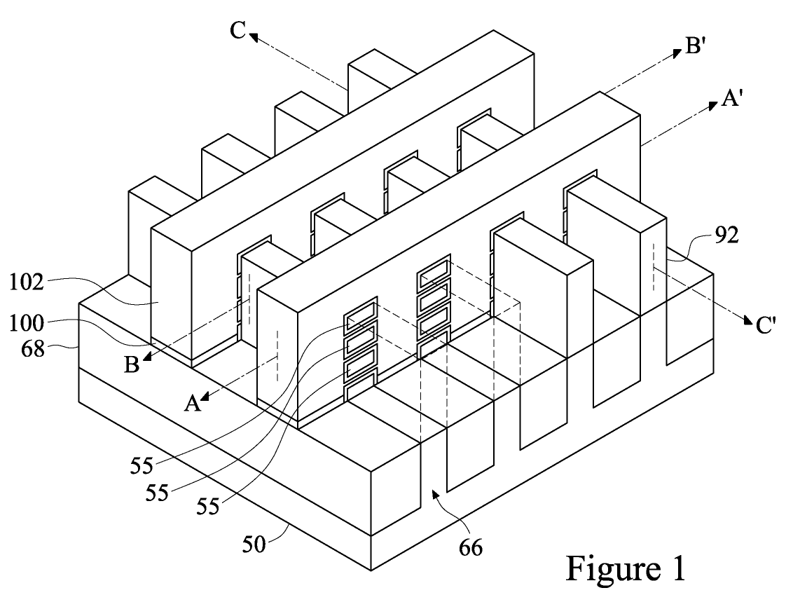

FIG. 1 illustrates an example of nano-FETs (e.g., nanowire FETs, nanosheet FETs, or the like) in a three-dimensional view. The nano-FETs comprise nanostructures 55 (e.g., nanosheets, nanowires, or the like) over fins 66 on a substrate 50 (e.g., a semiconductor substrate), wherein the nanostructures 55 act as channel regions for the nano-FETs. The nanostructures 55 may include p-type nanostructures, n-type nanostructures, or a combination thereof. Shallow trench isolation (STI) regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68. Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Reference cross-section A-A’ is along a longitudinal axis of a gate electrode 102 and in a direction, for example, perpendicular to the direction of current flow between the epitaxial source/drain regions 92 of a nano-FET. Reference cross-section B-B’ is parallel to the reference cross-section A-A’ and extends through epitaxial source/drain regions 92 of multiple nano-FETs. Reference cross-section C-C’ is perpendicular to the reference cross-section A-A’ and is parallel to a longitudinal axis of a fin 66 of the nano-FET and in a direction of, for example, a current flow between the epitaxial source/drain regions 92 of the nano-FET. Subsequent figures refer to these reference cross-sections for clarity. Some embodiments discussed herein are discussed in the context of nano-FETs formed using a gate-last process. In other embodiments, a gate-first process may be used. Also, some embodiments contemplate aspects used in planar devices, such as planar FETs or in FinFETs.

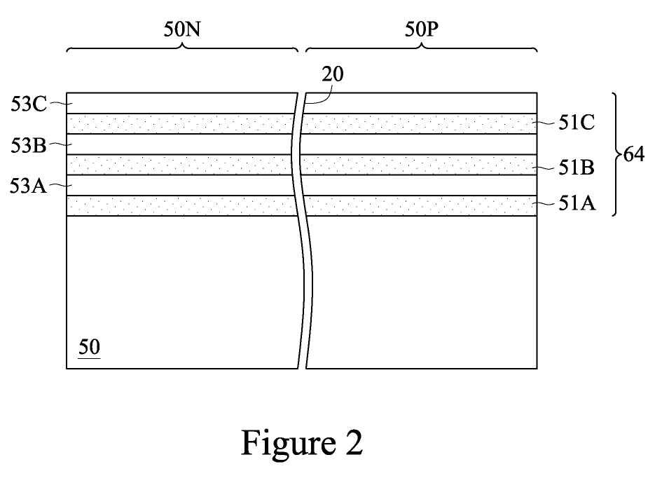

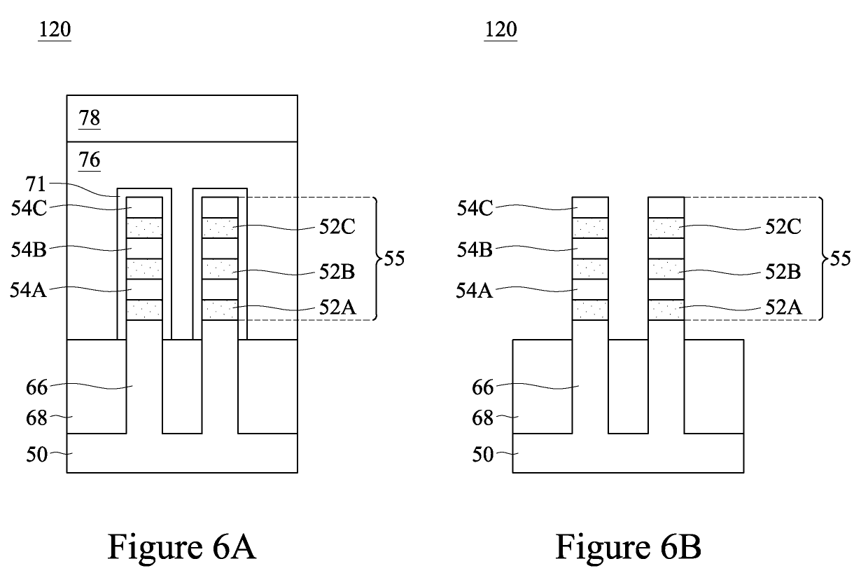

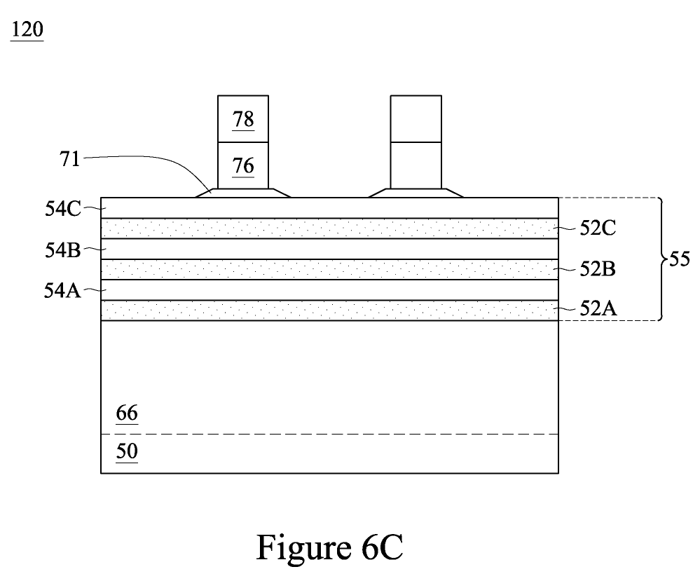

FIGS. 2-20C are views of intermediate processes in the manufacturing of a semiconductor device including nano-FET devices, in accordance with some embodiments. FIGS. 2, 3, 4, 5, 6A, 7A, 8A, 9A, 10A, 11A, 12A, 13A, 14A, 15A, 16A, 17A, 18A, 19A, and 20A illustrate cross-sectional views along the reference cross-section A-A’ illustrated in FIG. 1. FIGS. 6B, 7B, 8B, 9B, 10B, 11B, 11D, 12B, 13B, 14B, 15B, 16B, 17B, 18B, 19B, and 20B illustrate cross-sectional views along the reference cross-section B-B’ illustrated in FIG. 1. FIGS. 6C, 7C, 8C, 9C, 10C, 11C, 12C, 13C, 14C, 15C, 16C, 17C, 17F, 18C, 19C, and 20C illustrate cross-sectional views along the reference cross-section C-C’ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers 51 may be removed and the second semiconductor layers 53 may be patterned to form channel regions of nano-FETs in the n-type region 50N and the p-type region 50P. In some embodiments, the first semiconductor layers 51 are removed and the second semiconductor layers 53 are patterned to form channel regions of nano-FETs in the n-type region 50N, and the second semiconductor layers 53 are removed and the first semiconductor layers 51 are patterned to form channel regions of nano-FETs in the p-type region 50P. In some embodiments, the second semiconductor layers 53 are removed and the first semiconductor layers 51 are patterned to form channel regions of nano-FETs in the n-type region 50N, and the first semiconductor layers 51 are removed and the second semiconductor layers 53 are patterned to form channel regions of nano-FETs in the p-type region 50P. In some embodiments, the second semiconductor layers 53 are removed and the first semiconductor layers 51 are patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material different from the first semiconductor material, such as silicon or the like.

The first semiconductor materials and the second semiconductor materials may be materials having a high etching selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

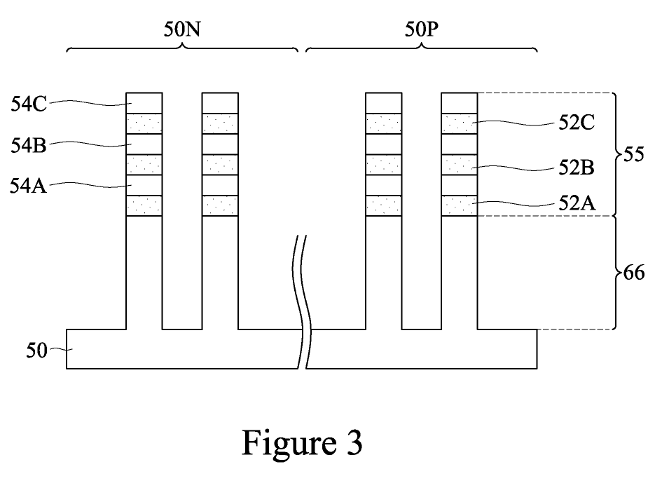

In FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

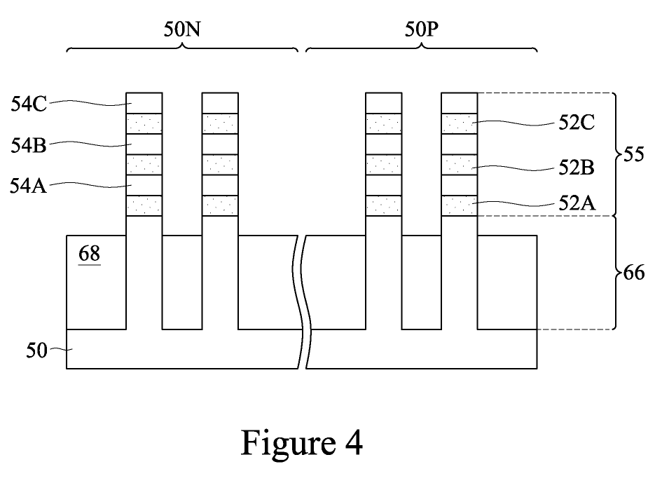

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, such as silicon nitride, the like, or a combination thereof, and may be formed by high-density plasma CVD (HDP-CVD), flowable CVD (FCVD), the like, or a combination thereof. Other insulation materials formed by any acceptable process may be used. An anneal process may be performed once the insulation material is formed. Although the insulation material is illustrated as a single layer, some embodiments may utilize multiple layers.

A removal process may be then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material may be substantially co-planar or level after the planarization process is complete. The insulation material may be then recessed to form the STI regions 68. The insulation material may be recessed such that upper portions of fins 66 in the n-type region 50N and the p-type region 50P protrude from between neighboring STI regions 68. The STI regions 68 may be recessed using an acceptable etching process, such as one that is selective to the material of the insulation material and etches the material of the insulation material at a faster rate than the material of the fins 66 and the nanostructures 55. For example, dilute hydrofluoric acid may be used when the insulation material is an oxide. After the removal process, the top surfaces of the STI regions 68 may have a flat surface as illustrated, a convex surface, a concave surface, or a combination thereof.

The process described above with respect to FIGS. 2-4 is one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) are illustrated and discussed herein as comprising the same materials in the p-type region 50P and the n-type region 50N, and the second semiconductor layers 53 (and resulting second nanostructures 54) are illustrated and discussed herein as comprising the same materials in the p-type region 50P and the n-type region 50N for illustrative purposes. In some embodiments, the first semiconductor layers 51 may comprise different materials in the p-type region 50P and the n-type region 50N. In some embodiments, the second semiconductor layers 53 may comprise different materials in the p-type region 50P and the n-type region 50N. In some embodiments, the first semiconductor layers 51 may comprise different materials in the p-type region 50P and the n-type region 50N, and the second semiconductor layers 53 may comprise different materials in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implantation, the photoresist may be removed, such as by an acceptable ashing process. After the implantations of the n-type region 50N and the p-type region 50P, an annealing may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

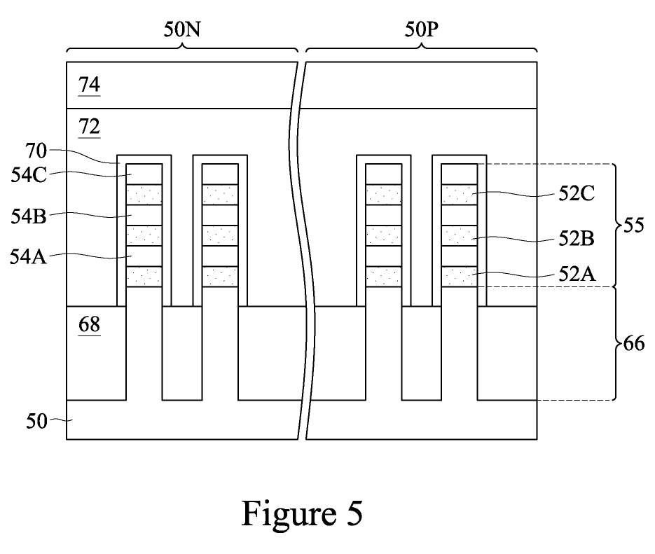

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited (e.g., using CVD, ALD, or the like), or thermally grown according to acceptable techniques. In an embodiment, the dummy dielectric layer 70 may comprise silicon oxycarbide (SiOC). A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity to the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A-20C illustrate various additional processes in the manufacturing of the nano-FET devices, in accordance to some embodiments. For example, the FIGS. 6A-20C are views of intermediate processes in the manufacturing of a semiconductor device 120 that includes the nano-FET devices, in accordance with some embodiments. FIGS. 6A-20C illustrate features in either or both the n-type region 50N or the p-type region 50P. In FIGS. 6A-6C, masks 78, dummy gates 76, and dummy gate dielectrics 71 are formed. The dummy gates 76 and dummy gate dielectrics 71 may be collectively referred to as dummy gate structures or dummy gate stacks. The mask layer 74 (see FIG. 5) may be patterned using suitable photolithography and etching processes to form the masks 78. The pattern of the masks 78 then may be transferred to the dummy gate layer 72 to form the dummy gates 76 using suitable etching processes. During the forming of the dummy gates 76, the dummy dielectric layer 70 is also etched using the masks 78 as etching masks in order to form the dummy gate dielectrics 71. The dummy gate dielectrics 71 may be disposed below the dummy gates 76, and portions of the dummy gate dielectrics 71 may extend laterally from under respective dummy gates 76 and past sidewalls of the respective dummy gates 76 as shown in FIG. 6C. In this way, a width of each of the dummy gate dielectrics 71 may be greater than a width of a respective overlying dummy gate 76. The dummy gates 76 cover respective channel regions of the fins 66 and the overlying respective nanostructures 55. The pattern of the masks 78 may be used to separate each of the dummy gates 76 from adjacent dummy gates 76. The dummy gates 76 may also have a lengthwise direction substantially perpendicular to the lengthwise direction of respective fins 66.

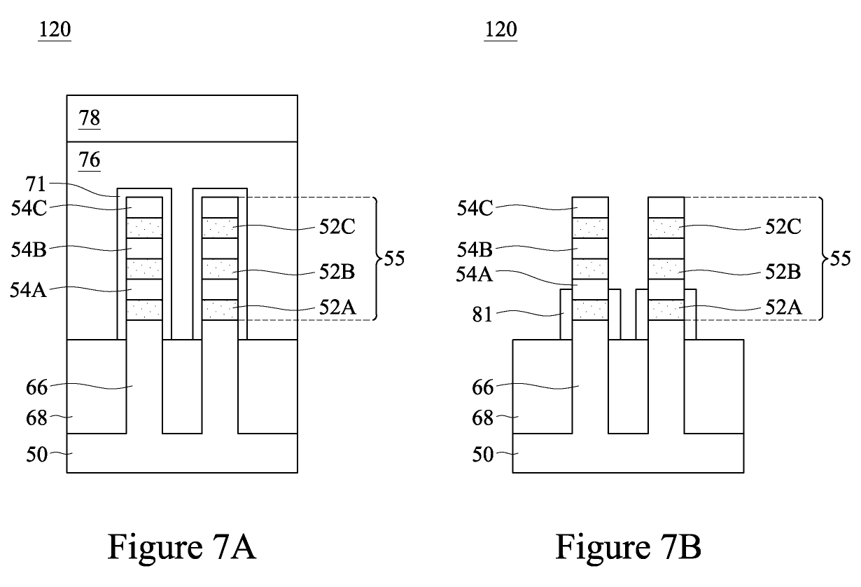

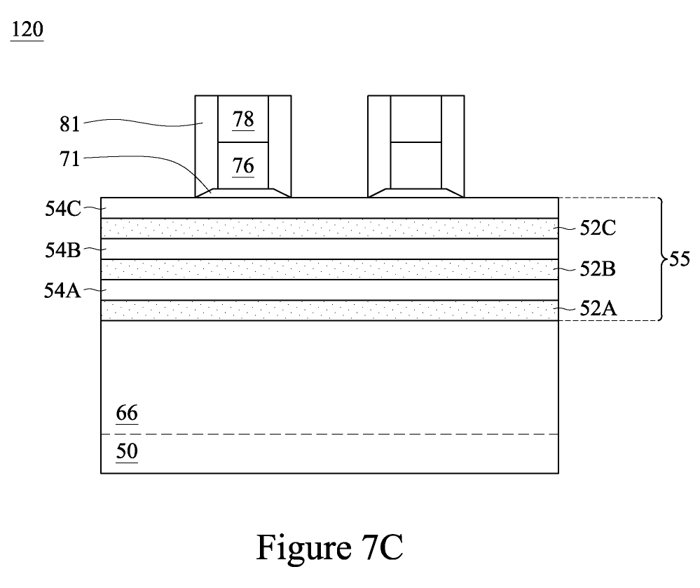

In FIGS. 7A-7C, spacers 81 are formed. The spacers 81 may self-align subsequently formed source/drain regions, as well as protect the dummy gate dielectrics 71 and the dummy gate 76 during subsequent etching processes. The spacers 81 may be a single layer of one material or multiple sub-layers of different materials with different etch rates. In some embodiments, the spacers 81 comprise two sub-layers with different materials of different etch rates, which may be selected from silicon oxide, silicon nitride, silicon oxynitride, silicon oxycarbide, or the like. The spacers 81 may be formed by forming a spacer layer by thermal oxidation or a suitable deposition process, such as CVD, ALD, or the like, and then patterning the spacer layer by a suitable etching process, such as an isotropic etching process (e.g., a wet etching process), an anisotropic etching process (e.g., a dry etching process), or the like. The spacer layer may be formed on top surfaces of the STI regions 68; top surfaces and sidewalls of the fins 66, the nanostructures 55, the dummy gate dielectrics 71, and the masks 78; and sidewalls of the dummy gates 76. After the etching process, the spacers 81 may remain on sidewalls of the fins 66 and/or nanostructures 55 as illustrated in FIG. 7B; sidewalls of the masks 78, and the dummy gates 76 as illustrated in FIG. 7C; and over the dummy gate dielectrics 71 (e.g., on sidewalls or top surfaces of the dummy gate dielectrics 71) as illustrated in FIG. 7C.

In the embodiments in which the spacers 81 comprise two sublayers with different materials, after the first sublayer is formed and prior to forming the second sublayer, implants for lightly-doped source/drain (LDD) regions (not separately illustrated) may be performed. Similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly-doped source/drain regions may have a concentration of impurities in a range from about 1x10¹⁵ atoms/cm³ to about 1x10¹⁹ atoms/cm³. An annealing may be used to repair implant damage and to activate the implanted impurities.

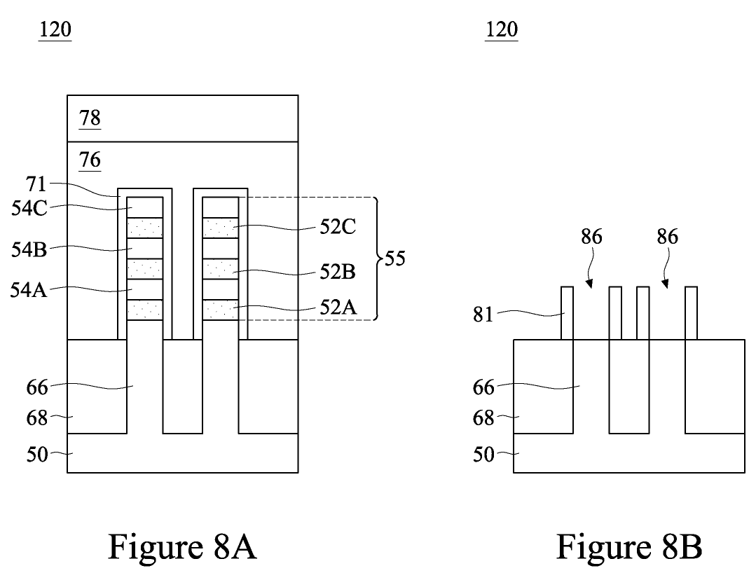

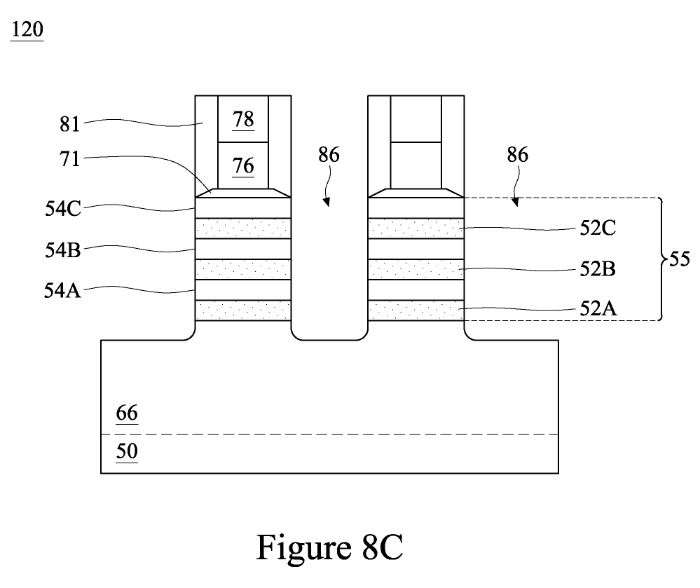

In FIGS. 8A-8C, first recesses 86 are formed in the fins 66 and the nanostructures 55. The first recesses 86 may extend through the first nanostructures 52 and the second nanostructures 54, and into the fins 66. As illustrated in FIG. 8B, top surfaces of the STI regions 68 (e.g., and top surfaces of the fins 66) may be level with bottom surfaces of the first recesses 86. In some embodiments, the bottom surfaces of the first recesses 86 are disposed below the top surfaces of the STI regions 68. The first recesses 86 may be formed by etching the fins 66, the nanostructures 55, and the substrate 50 using anisotropic etching processes, such as RIE, NBE, or the like. The spacers 81 and the masks 78 may mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching after the first recesses 86 reach desired depths.

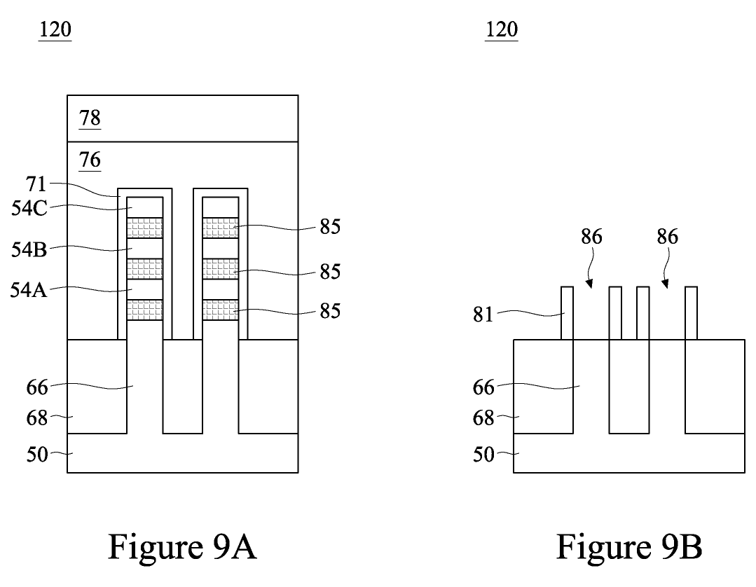

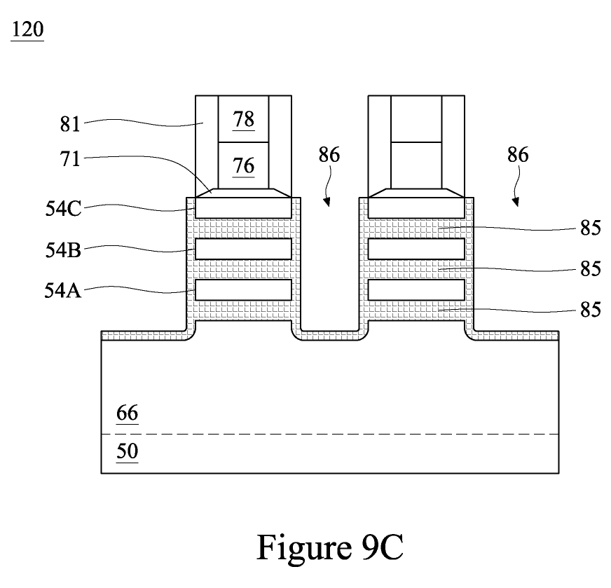

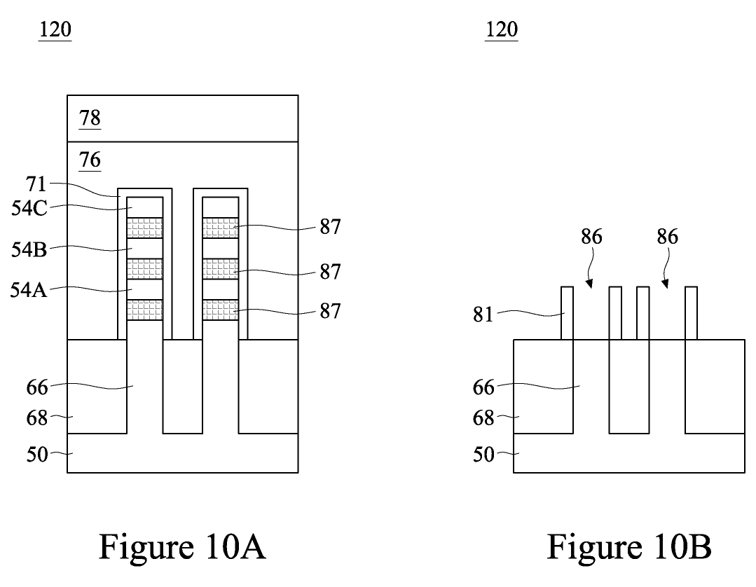

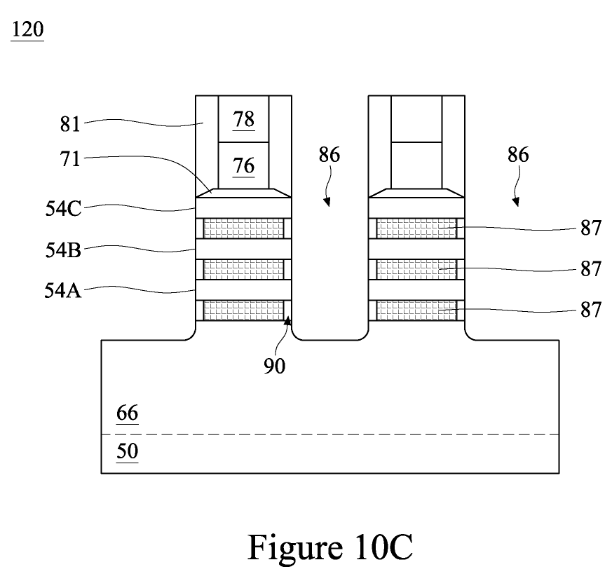

In FIGS. 9A-10C, the first nanostructures 52 are replaced with sacrificial layers 87. In FIGS. 9A-9C, the first nanostructures 52 may be removed using a suitable etching process, such as an isotropic etch process, performed through the first recesses 86. The etching process may selectively remove the material of the first nanostructures 52 without significantly removing materials of the second nanostructures 54 or the fins 66. In the embodiments in which the first nanostructures 52 comprise silicon germanium and the second nanostructures 54 comprise silicon, an etching process may be performed using tetramethylammonium hydroxide (TMAH), ammonium hydroxide (NH₄OH), or the like, as etchants, in order to remove the first nanostructures 52. The removal of the first nanostructures 52 results in spaces between adjacent ones of the second nanostructures 54, and between the second nanostructure 54A and the substrate 50, the spaces having previously been occupied by the first nanostructures 52 before they were removed.

Subsequently, an insulating material 85 may be formed to fill the spaces between adjacent ones of the second nanostructures 54, and between the second nanostructure 54A and the substrate 50. The insulating material 85 may be formed using a conformal deposition process, which is used to deposit the insulating material 85 on sidewalls and top surfaces of the fins 66, on sidewalls of the second nanostructures 54, and between the spaces between adjacent ones of the second nanostructures 54, and between the second nanostructure 54A and the substrate 50. For example, the insulating material 85 may be deposited using CVD, ALD, or the like. The insulating material 85 may comprise silicon oxide, or the like.

In FIGS. 10A-10C, an etching process is then performed to remove portions of the insulating material 85 on the sidewalls and the top surfaces of the fins 66, and on the sidewalls of the second nanostructures 54. After the etching process, the remaining insulating material 85 in the spaces between adjacent ones of the second nanostructures 54, and between the second nanostructure 54A and the substrate 50 forms the sacrificial layers 87. In addition, the etching process may also form second recesses, after which sidewalls of the sacrificial layers 87 are recessed (e.g., as shown in FIG. 10C) from sidewalls of the second nanostructures 54. The etching process may selectively remove the insulating material 85 without significantly removing materials of the second nanostructures 54 or the fins 66. The etching process may be isotropic or anisotropic. In some embodiments, the etching process may comprise a wet etching process that is performed using dilute HF, or the like, as an etchant. In some embodiments, the etching process may comprise a dry etching process that is performed using a mixture of NF₃ and NH₃, a mixture of HF and NH₃, or the like, as etchants. The sidewalls of the sacrificial layers 87 are illustrated as being straight in FIG. 10C as an example. However, the sidewalls of the sacrificial layers 87 may be concave or convex in some embodiments.

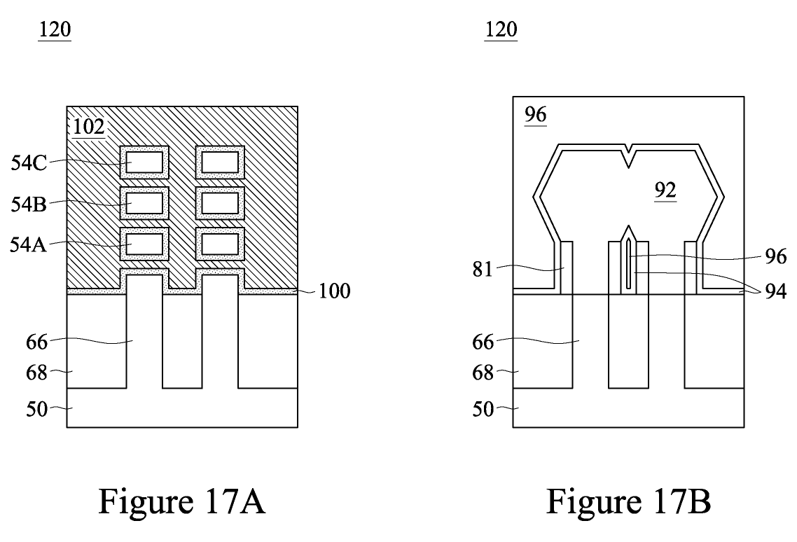

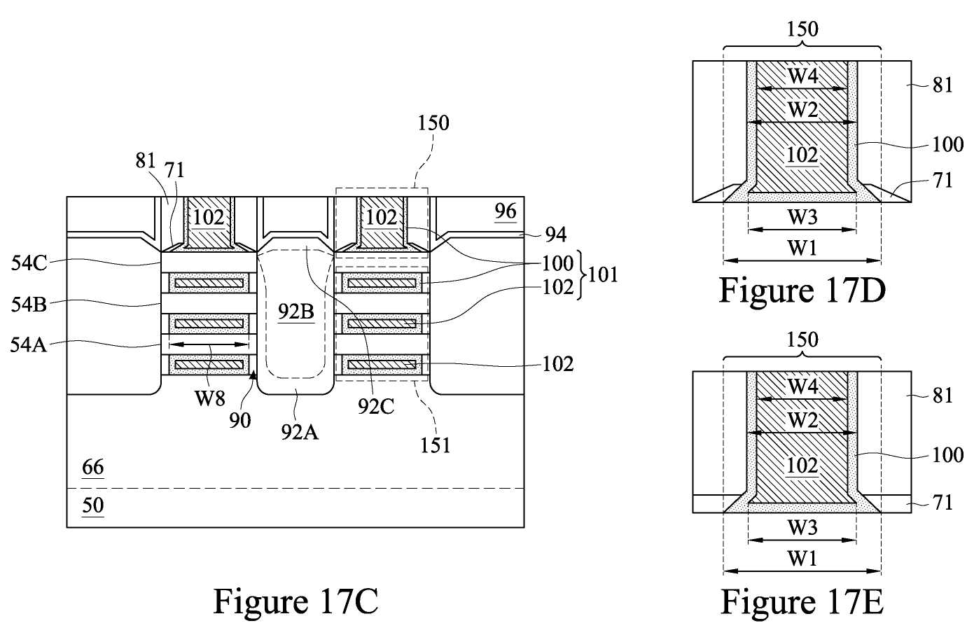

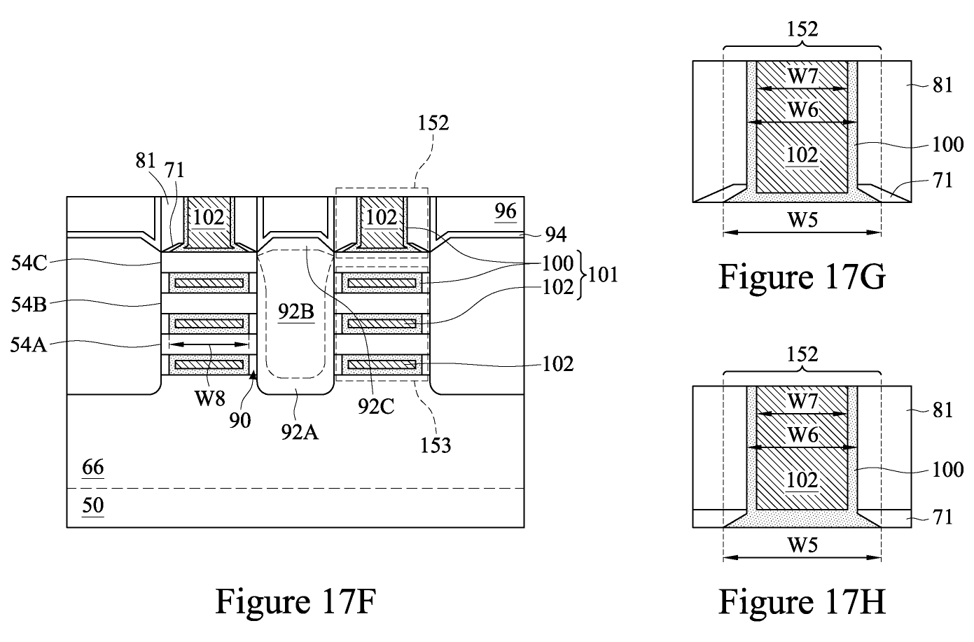

Referring further to FIGS. 10A-10C, after the formation of the sacrificial layers 87, inner spacers 90 are formed in the second recesses of the sacrificial layers 87. The inner spacers 90 may be formed by depositing an inner spacer layer (not separately illustrated) over the structure of the semiconductor device 120. The inner spacers 90 act as isolation features between subsequently formed source/drain regions and the gate dielectric layers 100 and the gate electrodes 102 (shown subsequently in FIGS. 17A-17C). As will be discussed in greater detail below, epitaxial source/drain regions and epitaxial materials will be formed in the first recesses 86, while the sacrificial layers 87 will be replaced with the gate dielectric layers 100 and the gate electrodes 102.

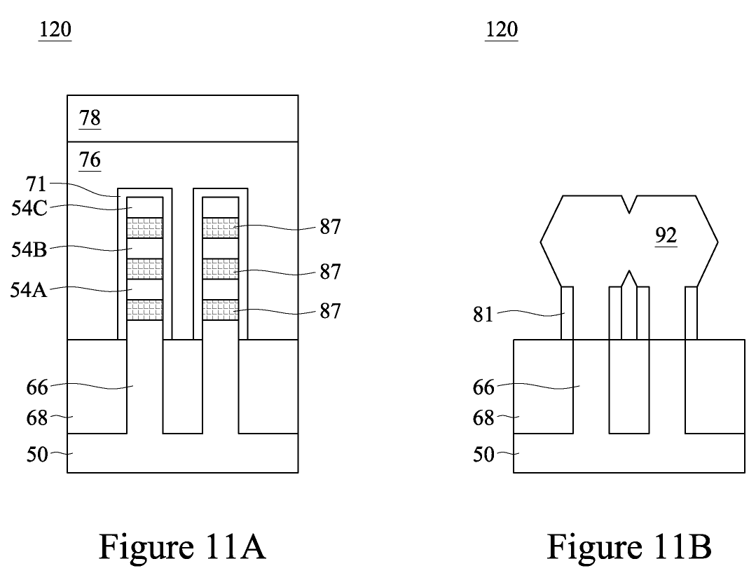

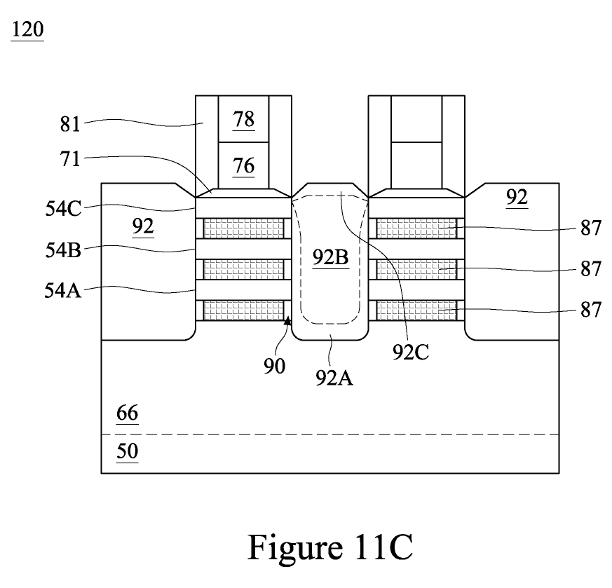

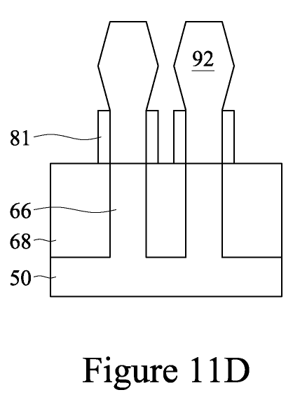

The inner spacer layer may be deposited by a conformal deposition process, such as CVD, ALD, or the like. The inner spacer layer may comprise a material such as silicon carbonitride (SiCN) or silicon oxycarbonitride (SiOCN). In other embodiments, silicon nitride or silicon oxynitride, or any suitable material, such as low-dielectric constant (low-k) materials having a k-value less than about 3.5, may be utilized. The inner spacer layer may then be anisotropically etched to form the inner spacers 90. Although outer sidewalls of the inner spacers 90 are illustrated as being flush with sidewalls of the second nanostructures 54, the outer sidewalls of the inner spacers 90 may extend beyond or be recessed from sidewalls of the second nanostructures 54. Moreover, although the outer sidewalls of the inner spacers 90 are illustrated as being straight in FIG. 10C, the outer sidewalls of the inner spacers 90 may be concave or convex. The inner spacer layer may be etched by an anisotropic etching process, such as RIE, NBE, or the like. The inner spacers 90 may be used to prevent damage to subsequently formed source/drain regions (shown in FIGS. 11A-11D) by subsequent etching processes, such as etching processes used to form the gate dielectric layers 100 and the gate electrodes 102 (shown subsequently in FIGS. 17A-17C).

In FIGS. 11A-11C, epitaxial source/drain regions 92 are formed in the first recesses 86. In some embodiments, the epitaxial source/drain regions 92 may exert stress on the second nanostructures 54, thereby improving performance. As illustrated in FIG. 11C, the epitaxial source/drain regions 92 are formed in the first recesses 86 such that each dummy gate 76 is disposed between respective neighboring pairs of the epitaxial source/drain regions 92. The sacrificial layers 87 may be separated from the epitaxial source/drain regions 92 by the inner spacers 90.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 may comprise materials exerting a compressive strain on the second nanostructures 54, such as silicon-germanium, boron doped silicon-germanium, germanium, germanium tin, or the like. The epitaxial source/drain regions 92 may have surfaces raised from respective surfaces of the nanostructures 55 and may have facets.

The epitaxial source/drain regions 92, the sacrificial layers 87, the second nanostructures 54, and/or the substrate 50 may be implanted with dopants to form source/drain regions, similar to the process previously discussed for forming lightly-doped source/drain regions, followed by an annealing process. The source/drain regions may have an impurity concentration of between about 1x10¹⁹ atoms/cm³ and about 1x10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 may have facets which expand laterally outward beyond sidewalls of the second nanostructures 54. In some embodiments, these facets cause adjacent epitaxial source/drain regions 92 of a same nano-FET to merge as illustrated by FIG. 11B. In some embodiments, adjacent epitaxial source/drain regions 92 remain separated after the epitaxy process is completed as illustrated by FIG. 11D.

The epitaxial source/drain regions 92 may comprise one or more semiconductor material layers. In some embodiments, the epitaxial source/drain regions 92 comprise first liner layers 92A on the sidewalls of the second nanostructures 54 and the inner spacers 90, second liner layers 92B on the first liner layers 92A, and fill layers 92C on the second liner layers 92B, as shown in FIG. 11C. The first liner layers 92A, the second liner layers 92B, and the fill layers 92C may be formed of different semiconductor materials and/or may be doped to different dopant concentrations. The first liner layers 92A may be grown first, the second liner layers 92B may be grown on the first liner layers 92A, and the fill layers 92C may be grown on the second liner layers 92B.

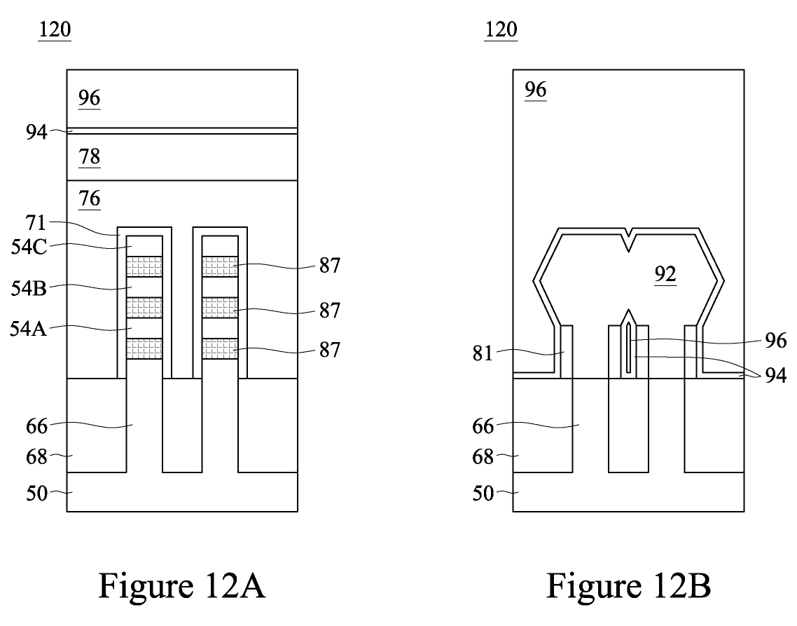

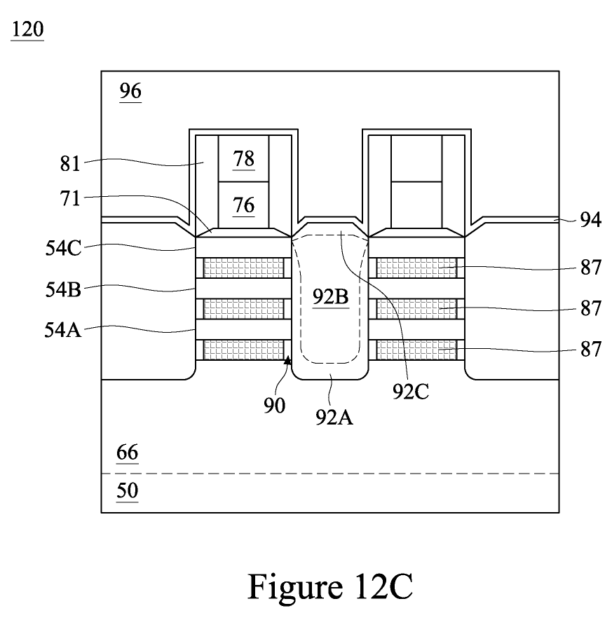

In FIGS. 12A-12C, a first interlayer dielectric (ILD) 96 is deposited over the structure illustrated in FIGS. 11A-11C. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the spacers 81. The CESL 94 may comprise a dielectric material, such as, silicon nitride, silicon oxide, silicon oxynitride, or the like, having a different etch rate than the material of the overlying first ILD 96.

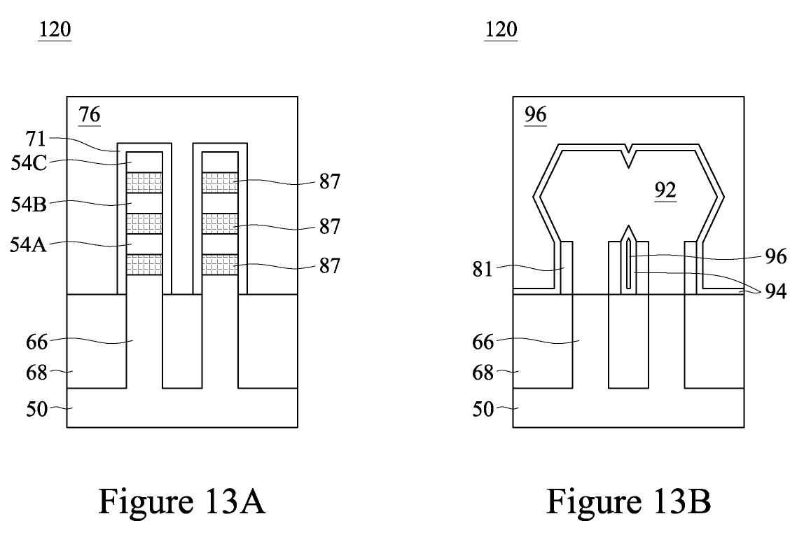

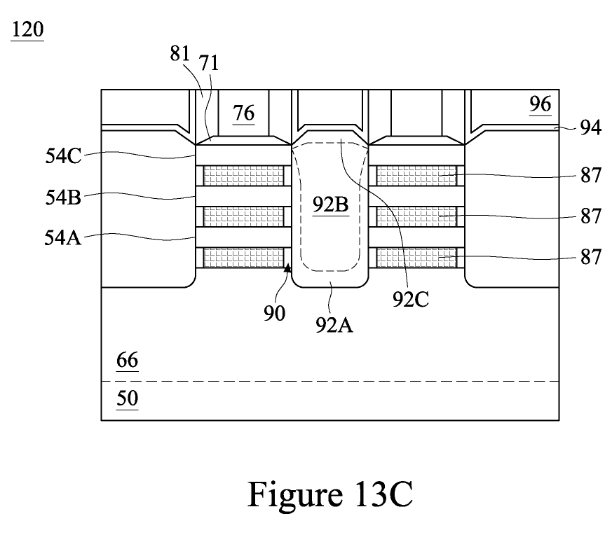

In FIGS. 13A-13C, a planarization process, such as CMP, may be performed to level the top surface of the first ILD 96 with the top surfaces of the dummy gates 76 or the masks 78. The planarization process may also remove the masks 78 on the dummy gates 76, and portions of the spacers 81 along sidewalls of the masks 78. After the planarization process, top surfaces of the dummy gates 76, the spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the spacers 81.

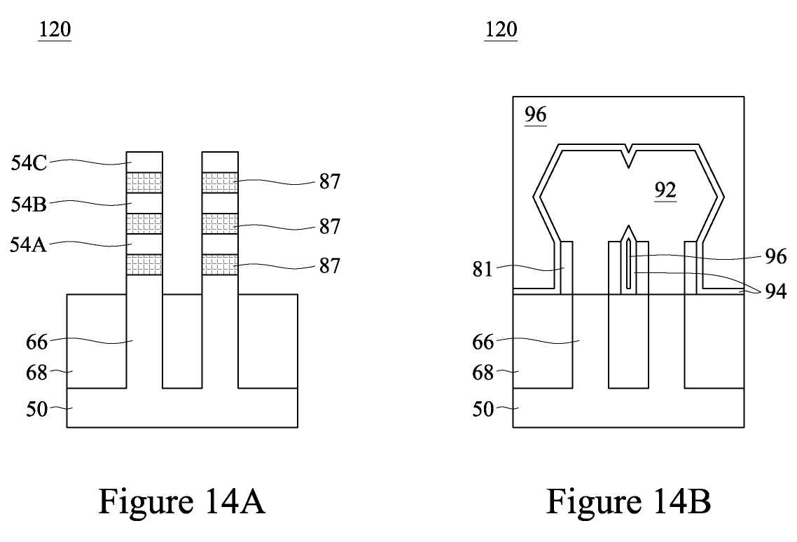

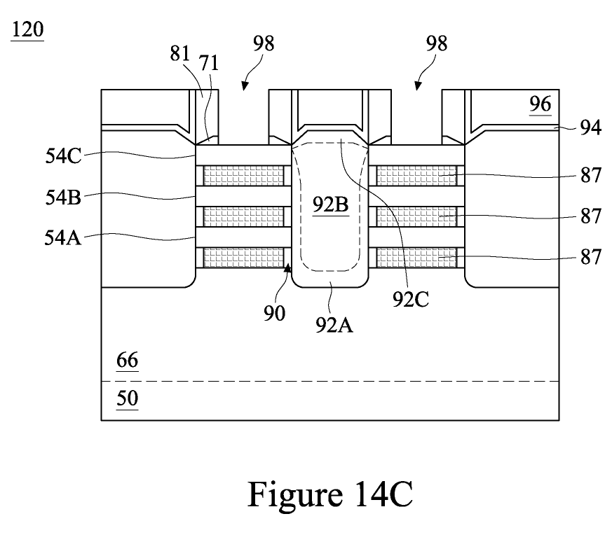

In FIGS. 14A-14C, the dummy gates 76 and portions of the dummy gate dielectrics 71 under the dummy gates 76 are removed in one or more etching processes to form third recesses 98. In some embodiments, the dummy gates 76 and the portions of the dummy gate dielectrics 71 are removed by an anisotropic dry etch process. For example, the etching processes may include performing a dry etching process using a chlorine or fluorine based etchant (e.g., HF gas, or the like) that selectively etches the dummy gates 76 and the portions of the dummy gate dielectrics 71 at faster rates than the first ILD 96 and/or the spacers 81. In other embodiments, the etching processes may include performing a wet etching process using a chlorine or fluorine based etchant. Each of the third recesses 98 exposes and/or overlies portions of nanostructures 55, which act as channel regions in subsequently completed nano-FETs. For example, after the dummy gates 76 and the portions of the dummy gate dielectrics 71 under the dummy gates 76 are removed using the one or more etching processes, a top surface and sidewalls of a topmost second nanostructure 54, and sidewalls of the other second nanostructures 54 are exposed within the third recess 98. The second nanostructures 54, which may subsequently act as channel regions, are disposed between neighboring pairs of the epitaxial source/drain regions 92. In addition, after the dummy gates 76 and the portions of the dummy gate dielectrics 71 under the dummy gates 76 are removed using the one or more etching processes, remaining portions of the dummy gate dielectrics 71 remain disposed under the spacers 81, wherein the remaining portions of the dummy gate dielectrics 71 are disposed between the spacers 81 and the topmost second nanostructure 54.

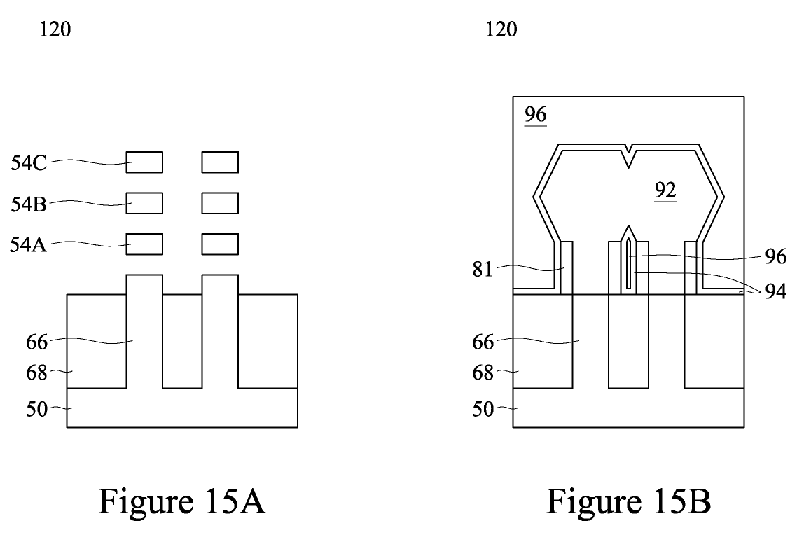

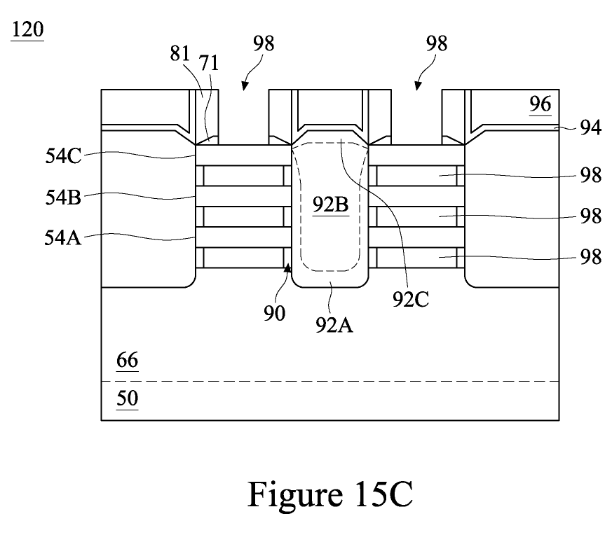

In FIGS. 15A-15C, the sacrificial layers 87 are removed, which extends the third recesses 98 between the second nanostructures 54. The sacrificial layers 87 may be removed by performing an isotropic etching process, such as wet etching, dry etching, or the like, using a chlorine or fluorine based etchant which may selectively remove the materials of the sacrificial layers 87, while the second nanostructures 54, the substrate 50, and the STI regions 68 may be at most slightly etched. For example, the etching process may comprise performing a dry etching process, wherein etchants used during the dry etching process include a mixture of NF₃ and NH₃, a mixture of HF and NH₃, or the like. In other embodiments, the etching process may comprise performing a wet etching process, wherein an etchant used during the wet etching process includes diluted HF, or the like. The inner spacers 90 may protect the epitaxial source/drain regions 92 during the etching process, so that the epitaxial source/drain regions 92 may remain unetched.

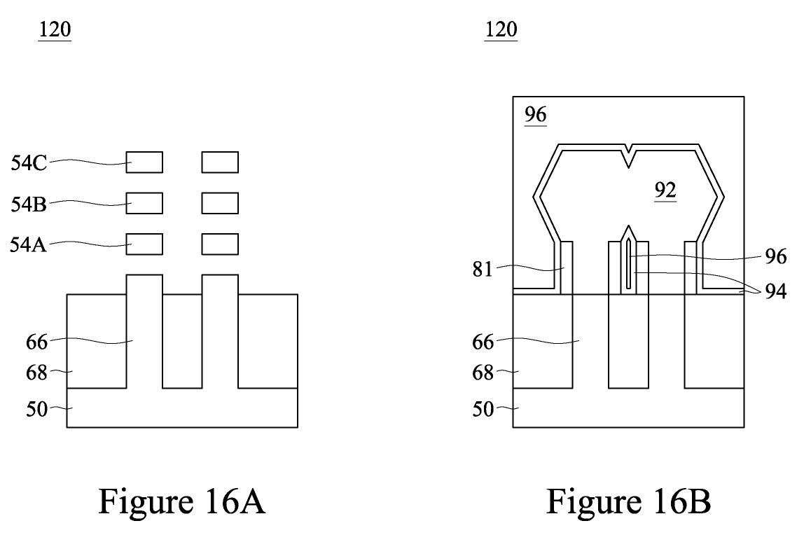

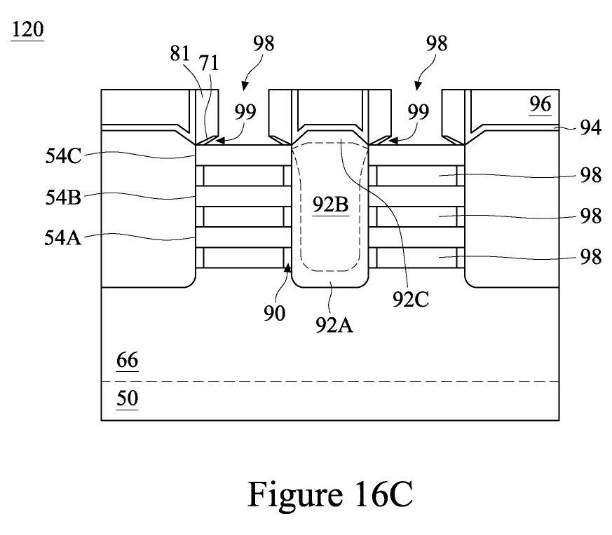

In FIGS. 16A-16C, after the sacrificial layers 87 are removed, an etching process is then performed to remove portions of the dummy gate dielectrics 71 that are disposed under the spacers 81. The etching process may form fourth recesses 99 (shown in FIG. 16C) that extend laterally under the spacers 81, wherein each third recess 98 may be connected to corresponding fourth recesses 99. After the etching process is performed, sidewalls of remaining portions of the dummy gate dielectrics 71 are recessed (e.g., as shown in FIG. 16C) from sidewalls of the spacers 81. The etching process may selectively remove the portions of the dummy gate dielectrics 71 without significantly removing materials of the second nanostructures 54, the fins 66, or the spacers 81. The etching process may be isotropic or anisotropic, and may comprise a wet etching process, a dry etching process, or the like, using a chlorine or fluorine based etchant. In some embodiments, the etching process may comprise a wet etching process that is performed using dilute HF, or the like, as an etchant. In some embodiments, the etching process may comprise a dry etching process that is performed using a mixture of NF₃ and NH₃, a mixture of HF and NH₃, or the like, as etchants. After the etching process, the sidewalls of the remaining portions of the dummy gate dielectrics 71 are illustrated as being sloped in FIG. 16C as an example. However, the sidewalls of the remaining portions of the dummy gate dielectrics 71 may be straight, concave, or convex in some embodiments.

In FIGS. 17A-17C, gate dielectric layers 100 and gate electrodes 102 are formed in the third recesses 98 and the fourth recesses 99. The gate dielectric layers 100 may be deposited conformally in the third recesses 98 and the fourth recesses 99. The gate dielectric layers 100 may be formed on top surfaces and sidewalls of the substrate 50 and the fins 66, and on top surfaces, sidewalls, and bottom surfaces of the second nanostructures 54. The gate dielectric layers 100 may also be formed on sidewalls, top surfaces, and bottom surfaces of the spacers 81, as well as the sidewalls of the remaining portions of the dummy gate dielectrics 71 in the fourth recesses 99. The gate dielectric layers 100 may also be deposited on top surfaces of the first ILD 96, the CESL 94, and the STI regions 68 as well as on sidewalls of the inner spacers 90. In an embodiment, the gate dielectric layers 100 may partially fill the fourth recesses 99 (e.g., as shown in FIGS. 17C-17E). In an embodiment, the gate dielectric layers 100 may completely fill the fourth recesses 99 (e.g., as shown in FIGS. 17F-17H).

In some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a dielectric constant (k) value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, or the like.

The gate electrodes 102 are deposited over the gate dielectric layers 100, respectively, and may fill the remaining portions of the third recesses 98 as well as the remaining portions of the fourth recesses 99 as shown in FIGS. 17C-17E. In other embodiments, the gate electrodes 102 may fill the remaining portions of the third recesses 98 as shown in FIGS. 17F-17H. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A and 17C, the gate electrodes 102 may comprise any number of liner layers, any number of work function tuning layers, and a fill material. Any combination of the layers which make up the gate electrodes 102 may be deposited between adjacent ones of the second nanostructures 54 and between the second nanostructure 54A and the substrate 50.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the third recesses 98 and the fourth recesses 99, a planarization process, such as CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as gate structures. The gate electrodes 102 and the gate dielectric layers 100 may also be referred to collectively as gate stacks 101. The inner spacers 90 may separate epitaxial source/drain regions 92 from the gate stacks 101 and provide sufficient electrical insulation between the epitaxial source/drain regions 92 and the gate stacks 101.

Referring further to FIGS. 17A-17C, the gate stack 101 comprises a first portion of the gate stack 150 (shown in FIG. 17C) that is disposed over and in physical contact with a top surface of the topmost one of the second nanostructures 54 (e.g., the second nanostructure 54C). In addition, the gate stack 101 also comprises a second portion of the gate stack 151 that is disposed between adjacent ones of the second nanostructures 54 and between the second nanostructure 54A and the substrate 50. As shown in FIGS. 17C, the fourth recesses 99 are filled with the gate electrodes 102 and the gate dielectric layers 100, such that the first portion of the gate stack 150 is wider at its base (e.g., also referred to as the gate stack footing) which contacts the top surface of the topmost second nanostructure 54 (e.g., the second nanostructure 54C) than other upper portions of the first portion of the gate stack 150.

FIG. 17D illustrates the first portion of the gate stack 150 that was shown previously in FIG. 17C. In FIG. 17D, the fourth recesses 99 are filled with the gate electrodes 102 and the gate dielectric layers 100. The first portion of the gate stack 150 may have a gate stack footing (e.g., a base of the first portion of the gate stack 150 that physically contacts the top surface of the second nanostructure 54C) that has a width W1. Additionally, a width between outermost points of the first portion of the gate stack 150 is equal to the width W1. In an embodiment, upper portions of the first portion of the gate stack 150 that are above the gate stack footing may have a width W2, wherein the width W1 is greater than the width W2. In an embodiment, a bottom surface of the gate electrodes 102 of the first portion of the gate stack 150 that is disposed above the top surface of the second nanostructure 54C has a width W3. Additionally, a width between outermost points of the gate electrodes 102 of the first portion of the gate stack 150 is equal to the width W3. In an embodiment, upper portions of the gate electrodes 102 of the first portion of the gate stack 150 may have a width W4, wherein the width W3 is greater than the width W3. In an embodiment, a difference between the width W1 and the width W2 may be in a range from 0.5 nm to 5 nm. In an embodiment, the second portion of the gate stack 151 may have a width W8. In an embodiment, an interface between a sidewall of the dummy gate dielectrics 71 and a sidewall of the gate dielectric layers 100 may be sloping at an angle. In an embodiment, an interface between a sidewall of the dummy gate dielectrics 71 and a sidewall of the spacer 81 may be sloping at an angle. In an embodiment, an interface between the dummy gate dielectrics 71 and the spacer 81 may be horizontal (e.g., as shown in FIG. 17E where the spacer 81 directly overlaps and is in physical contact with the dummy gate dielectrics 71 below it).

Advantages can be achieved by removing the dummy gates 76 and portions of the dummy gate dielectrics 71 under the dummy gates 76 using one or more etching processes to form the third recesses 98. Another etching process is then performed to remove portions of the dummy gate dielectrics 71 that are disposed under the spacers 81 and to form the fourth recesses 99 that extend laterally under the spacers 81, wherein each third recess 98 may be connected to corresponding fourth recesses 99. The gate dielectric layers 100 and gate electrodes 102 are then formed in the third recesses 98 and the fourth recesses 99 to form the gate stack 101, wherein the gate dielectric layers 100 and the gate electrodes 102 fill the fourth recesses 99. The gate stack 101 comprises the first portion of the gate stack 150 that is disposed over and in physical contact with a top surface of the topmost one of the second nanostructures 54 (e.g., the second nanostructure 54C which subsequently acts as a topmost channel region of the semiconductor device 120). The first portion of the gate stack 150 is wider at its base (e.g., also referred to as the gate stack footing) which contacts the top surface of the topmost second nanostructure 54 (e.g., the second nanostructure 54C) than other upper portions of the first portion of the gate stack 150. The gate stack footing may have the width W1, and the upper portions of the first portion of the gate stack 150 may have the width W2, wherein the width W1 is greater than the width W2. In addition, a difference between the width W1 and the width W2 may be in a range from 0.5 nm to 5 nm. These advantages include the ability to modify the gate stack 101 footing profile (e.g., by modifying a width of the gate stack footing) over the topmost channel region to allow for improved control of the flow of electrical current through the topmost channel region (e.g., the second nanostructure 54C). For example, the gate stack footing of the first portion of the gate stack 150 having the width W1 that is larger than the width W2 of the upper portions of the first portion of the gate stack 150, as well as the difference between the width W1 and the width W2 being in the range from 0.5 nm to 5 nm, allows for an improved ability to tune the amount of electrical current that flows through the topmost channel region. In addition, non-uniform doping profiles (e.g., as a result of using a dummy gate stack having a smaller width as an implantation mask) during ion

implantation or doping processes (e.g., as described previously in FIGS. 7A-7C) can be minimized as a result of using the dummy gate stack (e.g., including the dummy gate dielectrics 71) having a wider gate stack footing profile. As a result, device performance is improved. In addition, a ratio of the width W1 of the gate stack footing of the first portion of the gate stack 150 to the width W8 of the second portion of the gate stack 151 can be tuned in order to optimize device performance and device drive currents. Further, because the upper portions of the first portion of the gate stack 150 can be formed having the width W2 that is smaller than the width W1 of the gate stack footing of the first portion of the gate stack 150, the spacers 81 that are disposed on sidewalls of the first portion of the gate stack 150 may be formed to have larger widths, which increases electrical isolation between the first portion of the gate stack 150 and the adjacent epitaxial source/drain regions 92 that are disposed on opposing sides of the first portion of the gate stack 150. This results in a reduced risk of shorting between the first portion of the gate stack 150 and the adjacent epitaxial source/drain regions 92.

FIGS. 17F-17H illustrate an alternative embodiment. Unless specified otherwise, like reference numerals in this embodiment (and subsequently discussed embodiments) represent like components in the embodiment shown in FIGS. 1-17E formed by like processes. Accordingly, the process steps and applicable materials may not be repeated herein.

In FIG. 17F, the gate stack 101 comprises a first portion of the gate stack 152 that is disposed over and in physical contact with the top surface of the topmost one of the second nanostructures 54 (e.g., the second nanostructure 54C). In addition, the gate stack 101 also comprises a second portion of the gate stack 153 that is disposed between adjacent ones of the second nanostructures 54 and between the second nanostructure 54A and the substrate 50. As shown in FIGS. 17F, the fourth recesses 99 are filled with the gate dielectric layers 100, such that the first portion of the gate stack 152 is wider at its base (e.g., also referred to as the gate stack footing) which contacts the top surface of the topmost second nanostructure 54 (e.g., the second nanostructure 54C) than other upper portions of the first portion of the gate stack 152.

FIG. 17G illustrates the first portion of the gate stack 152 that was shown previously in FIG. 17F. In FIG. 17G, the fourth recesses 99 are filled with the gate dielectric layers 100. The first portion of the gate stack 152 may have a gate stack footing (e.g., a base of the first portion of the gate stack 152 that physically contacts the top surface of the second nanostructure 54C) that has a width W5. Additionally, a width between outermost points of the first portion of the gate stack 152 is equal to the width W5. In an embodiment, upper portions of the first portion of the gate stack 152 may have a width W6, wherein the width W5 is greater than the width W6. In an embodiment, the gate electrodes 102 of the first portion of the gate stack 152 that is disposed above the top surface of the second nanostructure 54C has a uniform width W7, wherein the width W7 is smaller than the width W5 and the width W6. In an embodiment, a difference between the width W5 and the width W6 may be in a range from 0.5 nm to 5 nm. In an embodiment, the second portion of the gate stack 153 may have the width W8. In an embodiment, an interface between a sidewall of the dummy gate dielectrics 71 and a sidewall of the gate dielectric layers 100 may be sloping at an angle. In an embodiment, an interface between a sidewall of the dummy gate dielectrics 71 and a sidewall of the spacer 81 may be sloping at an angle. In an embodiment, an interface between the dummy gate dielectrics 71 and the spacer 81 may be horizontal (e.g., as shown in FIG. 17H where the spacer 81 directly overlaps and is in physical contact with the dummy gate dielectrics 71 below it).

Advantages can be achieved by removing the dummy gates 76 and portions of the dummy gate dielectrics 71 under the dummy gates 76 using one or more etching processes to form the third recesses 98. Another etching process is then performed to remove portions of the dummy gate dielectrics 71 that are disposed under the spacers 81 and to form the fourth recesses 99 that extend laterally under the spacers 81, wherein each third recess 98 may be connected to corresponding fourth recesses 99. The gate dielectric layers 100 and gate electrodes 102 are then formed in the third recesses 98 and the fourth recesses 99 to form the gate stack 101, wherein the gate dielectric layers 100 fill the fourth recesses 99. The gate stack 101 comprises the first portion of the gate stack 152 that is disposed over and in physical contact with a top surface of the topmost one of the second nanostructures 54 (e.g., the second nanostructure 54C which subsequently acts as a topmost channel region of the semiconductor device 120). The first portion of the gate stack 152 is wider at its base (e.g., also referred to as the gate stack footing) which contacts the top surface of the topmost second nanostructure 54 (e.g., the second nanostructure 54C) than other upper portions of the first portion of the gate stack 152. The gate stack footing may have the width W5, and the upper portions of the first portion of the gate stack 152 may have the width W6, wherein the width W5 is greater than the width W6. In addition, a difference between the width W5 and the width W6 may be in a range from 0.5 nm to 5 nm. These advantages include the ability to modify the gate stack 101 footing profile (e.g., by modifying a width of the gate stack footing) over the topmost channel region to allow for improved control of the flow of electrical current through the topmost channel region (e.g., the second nanostructure 54C). For example, the gate stack footing of the first portion of the gate stack 152 having the width W5 that is larger than the width W6 of the upper portions of the first portion of the gate stack 152, as well as the difference between the width W5 and the width W6 being in the range from 0.5 nm to 5 nm, allows for an improved ability to tune the amount of electrical current that flows

through the topmost channel region. In addition, non-uniform doping profiles (e.g., as a result of using a dummy gate stack having a smaller width as an implantation mask) during ion implantation or doping processes (e.g., as described previously in FIGS. 7A-7C) can be minimized as a result of using the dummy gate stack (e.g., including the dummy gate dielectrics 71) having a wider gate stack footing profile. As a result, device performance is improved. In addition, a ratio of the width W5 of the gate stack footing of the first portion of the gate stack 152 to the width W8 of the second portion of the gate stack 153 can be tuned in order to optimize device performance and device drive currents. Further, because the upper portions of the first portion of the gate stack 152 can be formed having the width W6 that is smaller than the width W5 of the gate stack footing of the first portion of the gate stack 152, the spacers 81 that are disposed on sidewalls of the first portion of the gate stack 152 may be formed to have larger widths, which increases electrical isolation between the first portion of the gate stack 152 and the adjacent epitaxial source/drain regions 92 that are disposed on opposing sides of the first portion of the gate stack 152. This results in a reduced risk of shorting between the first portion of the gate stack 152 and the adjacent epitaxial source/drain regions 92.

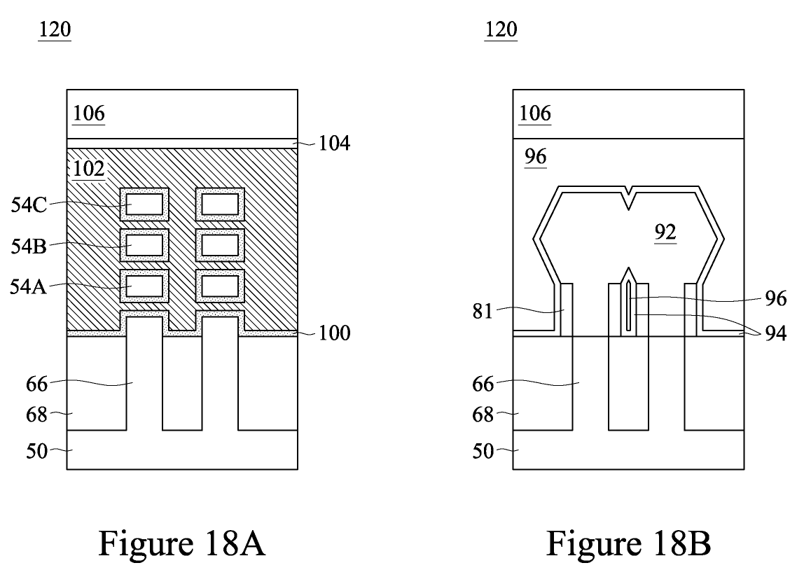

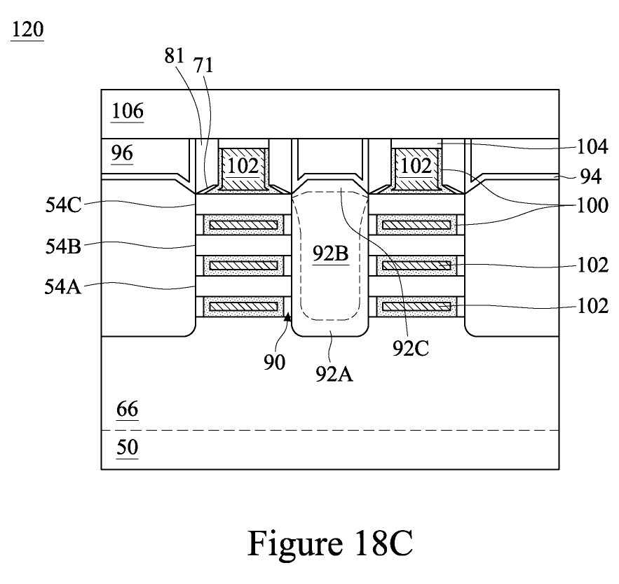

In FIGS. 18A-18C, the gate stacks 101 (including the gate dielectric layers 100 and the corresponding overlying gate electrodes 102) are recessed, gate masks 104 are formed in the recesses, and a second ILD 106 is formed over the first ILD 96 and the gate masks 104. The recesses may be formed directly over the gate stacks 101 and between opposing portions of spacers 81. Gate masks 104 may comprise one or more layers of dielectric material, such as silicon nitride, silicon oxynitride, or the like. A planarization process may be performed to remove excess material of the gate masks 104. The second ILD 106 may be formed of a dielectric material, such as PSG, BSG, BPSG, USG, or the like, and may be deposited by any suitable method, such as CVD, PECVD, FCVD, or the like.

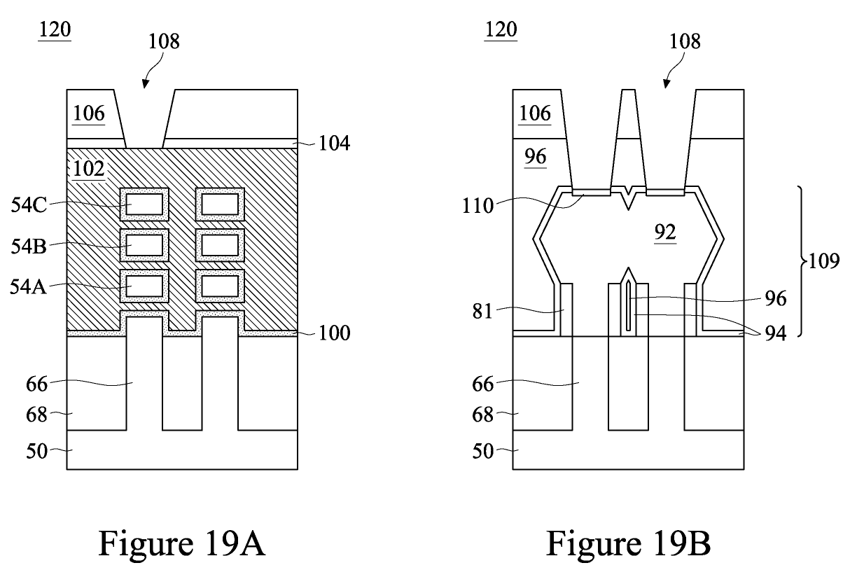

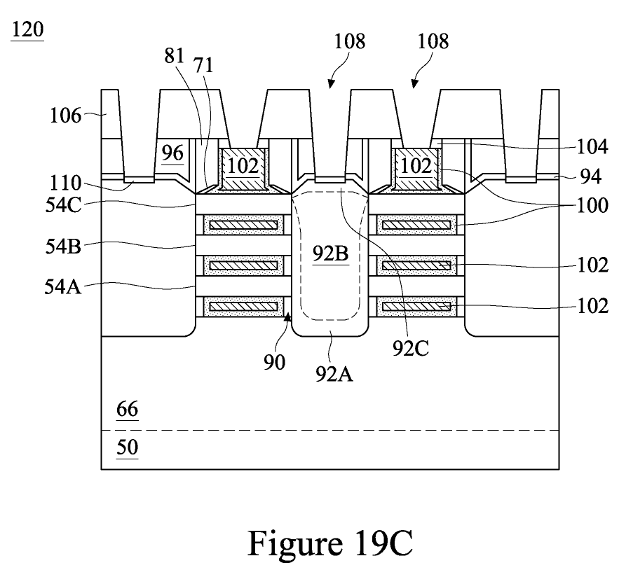

In FIGS. 19A-19C, the second ILD 106, the first ILD 96, the CESL 94, and the gate masks 104 are etched to form fifth recesses 108 exposing surfaces of the epitaxial source/drain regions 92 and/or some of the gate stacks 101. The fifth recesses 108 may be formed by etching using an anisotropic etching process, such as RIE, NBE, or the like. In some embodiments, the fifth recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the fifth recesses 108 extend into the epitaxial source/drain regions 92 and/or some of the gate stacks 101, and a bottom of the fifth recesses 108 may be level with (e.g., at a same level, or having a same distance from the substrate 50), or lower than (e.g., closer to the substrate 50) the epitaxial source/drain regions 92 and/or some of the gate stacks 101.

After the fifth recesses 108 are formed, first silicide regions 110 are formed over the epitaxial source/drain regions 92. In some embodiments, the first silicide regions 110 are formed by first depositing a metal (not separately illustrated) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal annealing process to form the first silicide regions 110. The un-reacted portions of the deposited metal are then removed, e.g., by an etching process. Although the first silicide regions 110 are referred to as silicide regions, the first silicide regions 110 may also be germanide regions, or silicon germanide regions (e.g., regions comprising silicide and germanide).

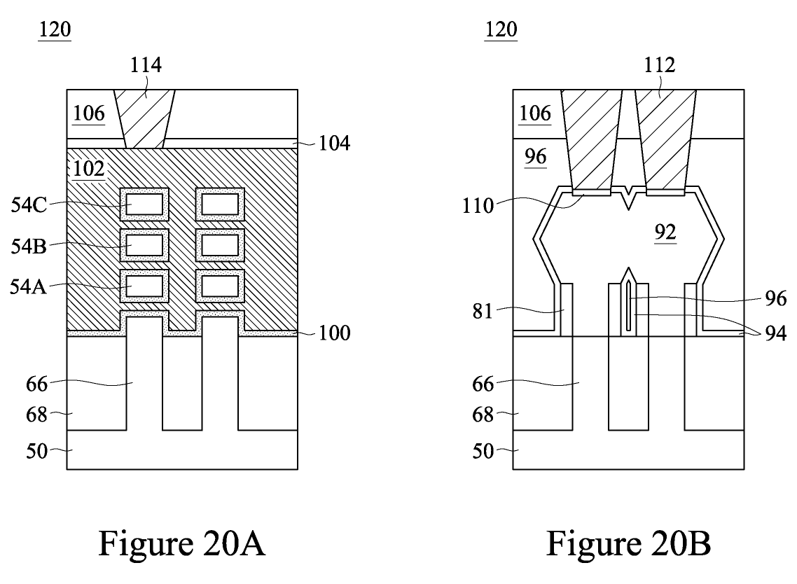

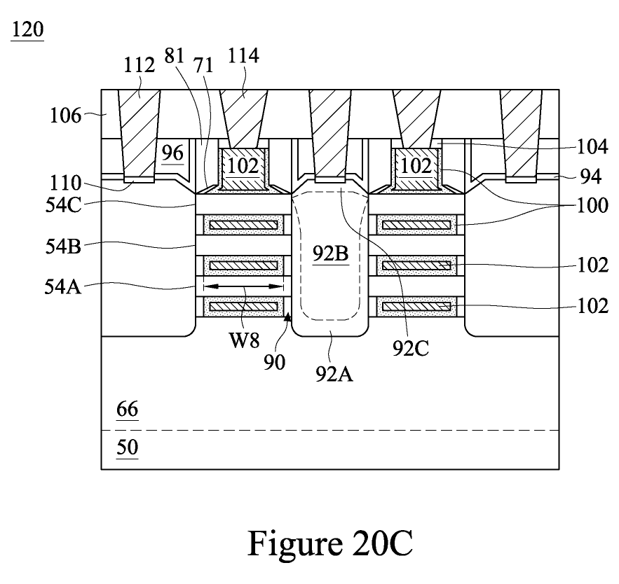

In FIGS. 20A-20C, source/drain contacts 112 and gate contacts 114, which may be also referred to as conductive contacts, are formed in the fifth recesses 108. The source/drain contacts 112 and the gate contacts 114 may each comprise one or more layers, such as barrier layers, diffusion layers, and fill materials. For example, in some embodiments, the source/drain contacts 112 and the gate contacts 114 each include a barrier layer and a conductive material, and are each electrically connected to an underlying conductive feature (e.g., a gate electrode 102 and/or a first silicide region 110). The gate contacts 114 are electrically connected to the gate electrodes 102 and the source/drain contacts 112 are electrically connected to the first silicide regions 110. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as CMP, may be performed to remove excess material from surfaces of the second ILD 106. The structure shown in FIGS. 20A-20C may be referred to as semiconductor device 120.

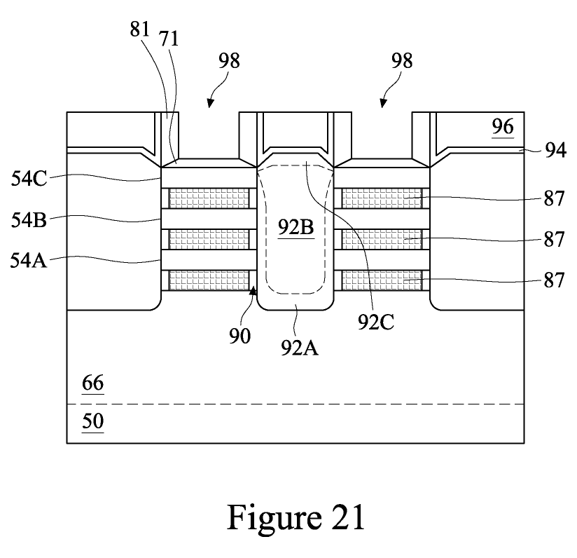

FIGS. 21-23C illustrate an alternative embodiment. Unless specified otherwise, like reference numerals in this embodiment (and subsequently discussed embodiments) represent like components in the embodiment shown in FIGS. 1-20C formed by like processes. Accordingly, the process steps and applicable materials may not be repeated herein. The initial steps of this embodiment are similar as shown in FIGS. 1-13C.

In FIG. 21, the dummy gate dielectrics 71 may comprise silicon oxycarbide (SiOC) that may be deposited using CVD, ALD, or the like. In other embodiments, the dummy gate dielectrics 71 may comprise a bi-layer that includes a silicon oxycarbide (SiOC) layer over a silicon oxide (SiO₂) layer. In an embodiment, the dummy gate dielectrics 71 may comprise silicon oxycarbide (SiOC) having a carbon atomic percentage composition of up to 10 percent. In FIG. 21, the dummy gates 76 are removed in one or more etching processes to form the third recesses 98. In some embodiments, the dummy gates 76 are removed by an anisotropic dry etch process. For example, the etching processes may include performing a dry etching process using a chlorine or fluorine based etchant (e.g., HF gas, or the like) that selectively etches the dummy gates 76 at faster rates than the dummy gate dielectrics 71, the first ILD 96 and/or the spacers 81. In other embodiments, the etching processes may include performing a wet etching process using a chlorine or fluorine based etchant. For example, the wet etching process may comprise using a mixture of dilute hydrofluoric acid (dHF) and ammonium hydroxide (NH₄OH). Each of the third recesses 98 exposes and/or overlies top surfaces of the dummy gate dielectrics 71.

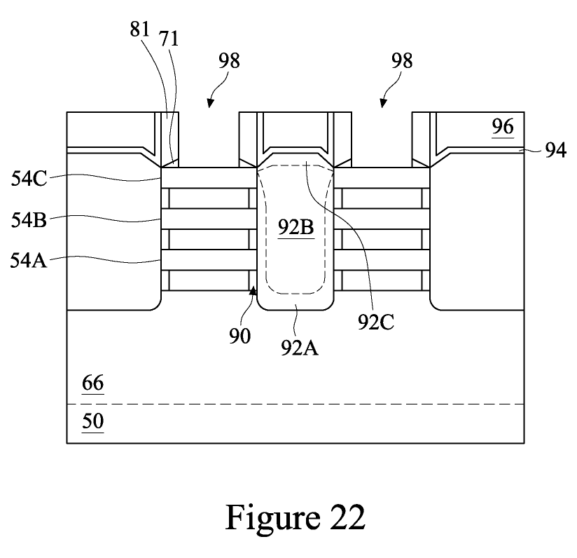

In FIG. 22, after the removal of the dummy gates 76, portions of the dummy gate dielectrics 71 that are exposed in the third recesses 98 are removed in one or more etching processes. In some embodiments, the portions of the dummy gate dielectrics 71 are removed by an anisotropic etching process. In an example, the etching processes may comprise performing a first etching process and a second etching process, wherein the first etching process is a plasma dry etching process that is performed using oxygen plasma that is generated from oxygen gas. In an embodiment, the first etching process is performed at a pressure that is in a range from 0 mT to 10000 mT. In an embodiment, the first etching process is performed using a radio frequency (RF) power source that is in a range from 0 W to 1500 W. After the first etching process is performed, the second etching process is performed, wherein the second etching process comprises a wet etching process that is performed using a mixture of hydrofluoric acid (HF) and ammonia (NH₃). In an embodiment, the second etching process is performed at a temperature that is in a range from 0° C to 300° C. The first etching process and the second etching process may be repeated in that order for a number of cycles. For example, the first etching process and the second etching process may be repeated in that order for up to 3 cycles. In other embodiments, the first etching process and the second etching process may be repeated in that order for more than 3 cycles. After the first etching process and the second etching process is performed, each of the third recesses 98 exposes and/or overlies portions of nanostructures 55, which act as channel regions in subsequently completed nano-FETs. For example, after the portions of the dummy gate dielectrics 71 are removed using the first etching process and the second etching process, a top surface and sidewalls of a topmost second nanostructure 54, and sidewalls of the other second nanostructures 54 are exposed within the third recess 98. The second nanostructures 54, which may subsequently act as channel regions, are disposed between neighboring pairs of the epitaxial source/drain regions 92. In addition, after the portions of the dummy gate dielectrics 71 are removed using the first etching process and the second etching process, remaining portions of the dummy gate dielectrics 71 remain disposed under the spacers 81, wherein the remaining portions of the dummy gate dielectrics 71 are disposed between the spacers 81 and the topmost second nanostructure 54.

Referring further to FIG. 22, the sacrificial layers 87 are removed, which extends the third recesses 98 between the second nanostructures 54. The sacrificial layers 87 may be removed by performing an isotropic etching process, such as wet etching, dry etching, or the like, using a chlorine or fluorine based etchant which may selectively remove the materials of the sacrificial layers 87, while the second nanostructures 54, the substrate 50, and the STI regions 68 may be at most slightly etched. For example, the etching process may comprise performing a wet etching process, wherein etchants used during the wet etching process comprise a mixture of diluted hydrofluoric acid (HF) and ammonium fluoride (NH₄F), or the like. The inner spacers 90 may protect the epitaxial source/drain regions 92 during the etching process, so that the epitaxial source/drain regions 92 may remain unetched.

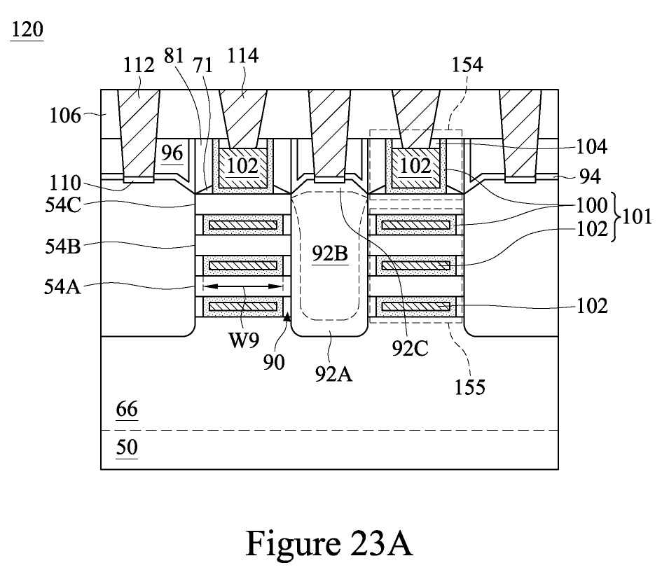

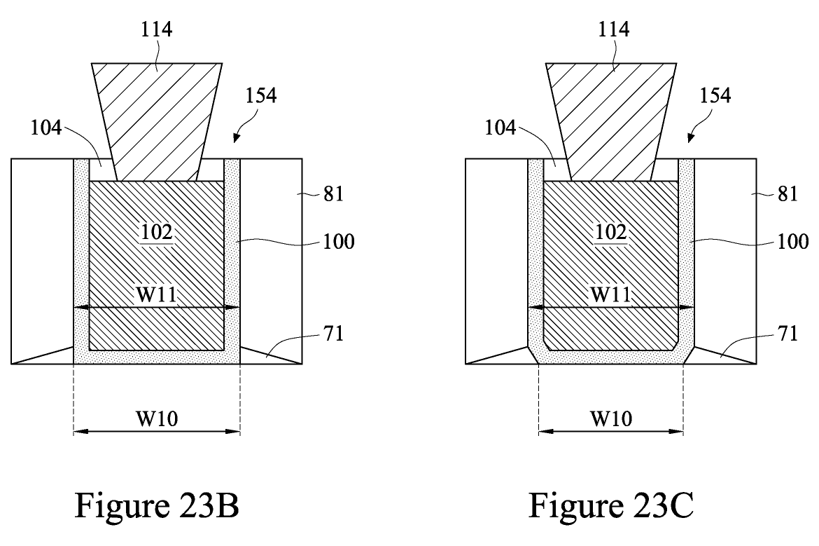

In FIG. 23A, the gate dielectric layers 100 and the gate electrodes 102 are formed in the third recesses 98. The gate dielectric layers 100 may be deposited conformally in the third recesses 98 using similar processes and similar materials as were described previously in FIGS. 17A-17C. The gate dielectric layers 100 may be formed on top surfaces and sidewalls of the substrate 50 and the fins 66, and on top surfaces, sidewalls, and bottom surfaces of the second nanostructures 54. The gate dielectric layers 100 may also be formed on sidewalls and top surfaces of the spacers 81, as well as the sidewalls of the remaining portions of the dummy gate dielectrics 71 that are disposed under the spacers 81. The gate dielectric layers 100 may also be deposited on top surfaces of the first ILD 96, the CESL 94, and the STI regions 68 as well as on sidewalls of the inner spacers 90. The gate electrodes 102 are deposited over the gate dielectric layers 100, respectively, and may fill the remaining portions of the third recesses 98. The gate electrodes 102 may be formed using similar processes and similar materials as were described previously in FIGS. 17A-17C. After the filling of the third recesses 98, a planarization process, such as CMP, may be performed as described previously in FIGS. 17A-17C to remove the excess portions of the gate dielectric layers 100 and the material of the gate electrodes 102, which excess portions are over the top surface of the first ILD 96. The remaining gate dielectric layers 100 and the gate electrodes 102 in the third recesses 98 form the gate stacks 101.

After the formation of the gate stacks 101, the gate stacks 101 (including the gate dielectric layers 100 and the corresponding overlying gate electrodes 102) are recessed, the gate masks 104 are formed in the recesses, and the second ILD 106 is formed over the first ILD 96 and the gate masks 104. The recesses may be formed directly over the gate stacks 101 and between opposing portions of the spacers 81. Gate masks 104 may comprise one or more layers of dielectric material, such as silicon nitride, silicon oxynitride, or the like. A planarization process may be performed to remove excess material of the gate masks 104. The second ILD 106 may be formed of a dielectric material, such as PSG, BSG, BPSG, USG, or the like, and may be deposited by any suitable method, such as CVD, PECVD, FCVD, or the like.

After the formation of the gate masks 104 and the second ILD 106, the fifth recesses 108 exposing surfaces of the epitaxial source/drain regions 92 and/or some of the gate stacks 101 are formed using similar processes as were described previously in FIGS. 19A-19C. After the formation of the fifth recesses 108, the source/drain contacts 112 and the gate contacts 114, which may be also referred to as conductive contacts, are formed in the fifth recesses 108 using similar processes and similar materials as were described previously in FIGS. 20A-20C.

Referring further to FIG. 23A, the gate stack 101 comprises a first portion of the gate stack 154 that is disposed over and in physical contact with a top surface of the topmost one of the second nanostructures 54 (e.g., the second nanostructure 54C). In addition, the gate stack 101 also comprises a second portion of the gate stack 155 that is disposed between adjacent ones of the second nanostructures 54 and between the second nanostructure 54A and the substrate 50. In an embodiment, the second portion of the gate stack 155 may have a width W9.

FIG. 23B illustrates the first portion of the gate stack 154 that was shown previously in FIG. 23A. The first portion of the gate stack 154 may comprise a bottom portion that is disposed between and in physical contact with sidewalls of the dummy gate dielectrics 71, wherein the bottom portion physically contacts the top surface of the second nanostructure 54C. In an embodiment, the bottom portion of the first portion of the gate stack 154 has a base (e.g., also referred to as the gate stack footing) which contacts the top surface of the topmost second nanostructure 54 (e.g., the second nanostructure 54C), wherein the gate stack footing has a width W10. In addition, the first portion of the gate stack 154 may comprise an upper portion that is disposed between and in physical contact with sidewalls of the spacers 81, wherein the upper portion of the first portion of the gate stack 154 is above and overlaps the bottom portion of the first portion of the gate stack 154. In an embodiment, the upper portion of the first portion of the gate stack 154 may have a width W11. In an embodiment, the width W10 is equal to the width W11.

In an embodiment, and as shown in FIG. 23C, the width W10 may be smaller than the width W11. In an embodiment, a difference between the width W11 and the width W10 may be in a range from 1.0 nm to 1.4 nm. In FIG. 23C, interfaces between the gate stack 101 and the dummy gate dielectrics 71 may be sloping at an angle, wherein the dummy gate dielectrics 71 extend laterally from under respective spacers 81 and past sidewalls of the respective spacers 81. In this way, a width of each of the dummy gate dielectrics 71 may be greater than a width of a respective overlying spacer 81.

Advantages can be achieved by forming the dummy gate dielectrics 71 comprising silicon oxycarbide (SiOC) having a carbon atomic percentage composition of up to 10 percent. The dummy gates 76 are removed in one or more etching processes to form third recesses 98 to expose top surfaces and sidewalls of the dummy gate dielectrics 71. After the removal of the dummy gates 76, portions of the dummy gate dielectrics 71 that are exposed in the third recesses 98 are removed in one or more etching processes, such that after the one or more etching processes, a top surface and sidewalls of a topmost second nanostructure 54, and sidewalls of the other second nanostructures 54 are exposed within the third recess 98, and remaining portions of the dummy gate dielectrics 71 remain disposed under the spacers 81. In addition, the dummy gate dielectrics 71 may extend laterally from under respective spacers 81 and past sidewalls of the respective spacers 81. In this way, a width of each of the dummy gate dielectrics 71 may be greater than a width of a respective overlying spacer 81. The sacrificial layers 87 may then be removed using an etching process, which extends the third recesses 98 between the second nanostructures 54. The gate stacks 101 (including the gate dielectric layers 100 and the corresponding overlying gate electrodes 102) may then be formed in the third recesses 98. The gate stack 101 may comprise a first portion of the gate stack 154 that is disposed over and in physical contact with a top surface of the topmost one of the second nanostructures 54 (e.g., the second nanostructure 54C). The bottom portion of the first portion of the gate stack 154 is disposed between sidewalls of the dummy gate dielectrics 71. The bottom portion of the first portion of the gate stack 154 has a base (e.g., also referred to as the gate stack footing) which contacts the top surface of the topmost second nanostructure 54 (e.g., the second nanostructure 54C), wherein the gate stack footing has a width W10. The upper portion of the first portion of the gate stack 154 is disposed between sidewalls of the spacers 81, wherein the upper portion of the first portion of the gate stack 154 may have a width W11. In an embodiment, the width W10 is smaller than the width W11, and a difference between the width W11 and the width W10 may be in a range from 1.0 nm to 1.4 nm.

These advantages include a reduction in a loss of material of the second nanostructures 54 during the performing of the one or more etching processes to remove the portions of the dummy gate dielectrics 71 that are exposed in the third recesses 98. This is because of a lower etch rate of a material of the dummy gate dielectrics 71 during the one or more etching processes, which prevents over etching of the underlying top surface and the sidewalls of the topmost second nanostructure 54, and the sidewalls of the other second nanostructures 54. The second nanostructures 54 subsequently act as channel regions of the semiconductor device 120, and hence, a degradation of device performance may be minimized, and device reliability may be enhanced. In addition, a risk of a loss of material of the dummy gate dielectric 71 below the spacers 81 is reduced during the performing of the one or more etching processes to remove the portions of the dummy gate dielectrics 71, and during the removal of the sacrificial layers 87 using the etching process. As a result, the remaining portions of the dummy gate dielectrics 71 remain disposed under the spacers 81, and the dummy gate dielectrics 71 may extend laterally from under respective spacers 81 and past sidewalls of the respective spacers 81. This helps prevent unintended leakage of current that could have occurred through leak paths under the spacers 81 from the bottom corners of the subsequently formed gate stack 101. As a result, device yield may be improved and device performance may be enhanced. For example, when a difference between the width W11 and the width W10 is greater than 1.4 nm, this may result in inadequate control of the flow of electrical current through the topmost channel region (e.g., the second nanostructure 54C).

In accordance with an embodiment, a method includes depositing a multi-layer stack over a semiconductor substrate, the multi-layer stack including a plurality of first sacrificial layers that alternate with a plurality of channel layers; forming a dummy gate structure over sidewalls and a top surface of the multi-layer stack, the dummy gate structure including a dummy gate over a dummy gate dielectric layer; forming spacers on sidewalls of the dummy gate and over the dummy gate dielectric layer; performing a first etching process to remove the dummy gate and a first portion of the dummy gate dielectric layer under the dummy gate to form a first recess, where after performing the first etching process, second portions of the dummy gate dielectric layer remain disposed under respective spacers; forming second recesses in respective ones of the second portions of the dummy gate dielectric layer, where each of the second recesses extends laterally under a respective spacer, and where the second recesses are connected to the first recess; and forming a gate structure in the first recess and the second recesses. In an embodiment, after forming the dummy gate structure over the sidewalls and the top surface of the multi-layer stack, a width of the dummy gate dielectric layer is greater than a width of the dummy gate, where performing the first etching process includes performing a dry etch process or a wet etch process using a chlorine or a fluorine based etchant, and where performing the first etching process to form the first recess exposes a top surface of a topmost channel layer of the plurality of channel layers. In an embodiment, forming the second recesses in respective ones of the second portions of the dummy gate dielectric layer includes performing a second etching process using a chlorine or fluorine based etchant. In an embodiment, the method further includes replacing the first sacrificial layers with second sacrificial layers, where a material of the first sacrificial layers is different from a material of the second sacrificial layers. In an embodiment, the gate structure has a gate stack footing that is in physical contact with a top surface of a topmost channel layer of the plurality of channel layers, and where a first width of the gate stack footing is greater than a second width of upper portions of the gate stack that are above the gate stack footing. In an embodiment, a difference between the first width and the second width is in a range from 0.5 nm to 5 nm. In an embodiment, forming the gate structure includes forming a gate dielectric layer in the first recess and the second recesses; and forming a gate electrode over the gate dielectric layer in the first recess and the second recesses. In an embodiment, forming the gate structure includes forming a gate dielectric layer in the first recess and the second recesses, where the gate dielectric layer fills the second recesses; and forming a gate electrode over the gate dielectric layer in the first recess.

In accordance with an embodiment, a method includes depositing a first sacrificial layer over a semiconductor substrate; depositing a first channel layer over the first sacrificial layer; forming a dummy gate structure over a top surface and sidewalls of the first channel layer, the dummy gate structure including a dummy gate over a dummy gate dielectric layer; forming spacers on opposing sidewalls of the dummy gate, where the spacers are disposed over and in physical contact with the dummy gate dielectric layer; removing the dummy gate and a first portion of the dummy gate dielectric layer under the dummy gate to form a first recess, where the first recess exposes a top surface of the first channel layer, where after forming the first recess, second portions of the dummy gate dielectric layer remain disposed under respective spacers; performing a first etching process to form second recesses in respective ones of the second portions of the dummy gate dielectric layer, where each of the second recesses is connected to the first recess and extends laterally under a respective spacer; and forming a gate structure in the first recess and the second recesses. In an embodiment, the method further includes replacing the first sacrificial layer with a second sacrificial layer, where a material of the first sacrificial layer is different from a material of the second sacrificial layer. In an embodiment, the material of the first sacrificial layer includes silicon germanium and the material of the second sacrificial layer includes silicon oxide. In an embodiment, performing the first etching process includes performing a dry etch process or a wet etch process using a chlorine or a fluorine based etchant. In an embodiment, the gate structure has a base that is in physical contact with the top surface of the first channel layer, where the base of the gate structure has a first width, where upper portions of the gate structure above the base have a second width, and where the first width is greater than the second width. In an embodiment, a difference between the first width and the second width is in a range from 0.5 nm to 5 nm. In an embodiment, forming the gate structure includes forming a gate dielectric layer in the first recess and the second recesses, where the gate dielectric layer fills the second recesses.

In accordance with an embodiment, a semiconductor device includes a gate structure over a semiconductor substrate, where the gate structure includes a first portion of the gate structure disposed between sidewalls of a dielectric layer; and a second portion of the gate structure disposed above the first portion of the gate structure; source/drain regions over the semiconductor substrate and on opposing sides of the gate structure; a first channel layer disposed between the source/drain regions and over the semiconductor substrate; and spacers on opposing sidewalls of the second portion of the gate structure, where the spacers are disposed over the dielectric layer. In an embodiment, the first portion of the gate structure has a base that is in physical contact with a top surface of the first channel layer, where the base has a first width, where the second portion of the gate structure has a second width, and where the first width is smaller than the second width. In an embodiment, a difference between the second width and the first width is in a range from 1.0 nm to 1.4 nm. In an embodiment, an interface between the dielectric layer and the first portion of the gate structure is sloped. In an embodiment, the dielectric layer is in physical contact with the top surface of the first channel layer, and where the dielectric layer includes silicon oxycarbide (SiOC).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
source/drain regions on opposing sides of a first channel layer;
a gate structure between the source/drain regions, the gate structure comprising:
a first portion of the gate structure disposed over and in physical contact with a top surface of the first channel layer, wherein the first portion of the gate structure comprises a base having a first width and an upper portion above the base having a second width, wherein the first width is greater than the second width; and
a second portion of the gate structure disposed below the first portion; and
spacers on opposing sidewalls of the upper portion of the first portion of the gate structure, wherein the spacers are disposed over and overlap the base of the first portion of the gate structure.

2. The semiconductor device of claim 1, wherein a difference between the first width and the second width is in a range from 0.5 nm to 5 nm.

3. The semiconductor device of claim 1, wherein the gate structure comprises a gate dielectric layer and a gate electrode over the gate dielectric layer, wherein a bottom surface of the gate electrode disposed over the top surface of the first channel layer has a third width, wherein an upper portion of the gate electrode has a fourth width, and wherein the third width is greater than the fourth width.

4. The semiconductor device of claim 1, further comprising a dielectric layer disposed between the base of the first portion of the gate structure and the spacers.

5. The semiconductor device of claim 4, wherein the dielectric layer is in physical contact with the top surface of the first channel layer, and wherein the dielectric layer comprises silicon oxycarbide (SiOC).

6. The semiconductor device of claim 5, wherein an interface between the dielectric layer and the first portion of the gate structure is sloped.

7. The semiconductor device of claim 1, further comprising a second channel layer, wherein the second portion of the gate structure is disposed between the first channel layer and the second channel layer.

8. A semiconductor device comprising:
a gate structure between source/drain regions, the gate structure comprising:
a first portion of the gate structure disposed over and in physical contact with a top surface of a first channel layer; and
a second portion of the gate structure disposed below the first portion; and
a dielectric layer disposed laterally adjacent to the first portion of the gate structure, wherein an interface between the dielectric layer and the first portion of the gate structure is sloped; and
spacers disposed over the dielectric layer and on opposing sidewalls of the first portion of the gate structure.

9. The semiconductor device of claim 8, wherein the first portion of the gate structure comprises a base having a first width and an upper portion above the base having a second width, wherein the first width is greater than the second width.

10. The semiconductor device of claim 9, wherein a difference between the first width and the second width is in a range from 0.5 nm to 5 nm.

11. The semiconductor device of claim 8, wherein the dielectric layer is in physical contact with the top surface of the first channel layer.

12. The semiconductor device of claim 11, wherein the dielectric layer comprises silicon oxycarbide (SiOC).

13. The semiconductor device of claim 8, further comprising a second channel layer, wherein the second portion of the gate structure is disposed between the first channel layer and the second channel layer.

14. A method comprising:
depositing a multi-layer stack over a semiconductor substrate, the multi-layer stack comprising a plurality of first sacrificial layers that alternate with a plurality of channel layers;
forming a dummy gate structure over sidewalls and a top surface of the multi-layer stack, the dummy gate structure comprising a dummy gate over a dummy gate dielectric layer, wherein a width of the dummy gate dielectric layer is greater than a width of the dummy gate;
forming spacers over the dummy gate dielectric layer and on sidewalls of the dummy gate;
removing the dummy gate and a first portion of the dummy gate dielectric layer under the dummy gate to form a first recess that exposes a topmost channel layer of the plurality of channel layers, wherein after exposing the topmost channel layer of the plurality of channel layers, second portions of the dummy gate dielectric layer remain disposed under respective spacers;
performing an etching process to form second recesses in respective ones of the second portions of the dummy gate dielectric layer, wherein each of the second recesses extends laterally under a respective spacer, and wherein the second recesses are connected to the first recess; and
forming a gate structure in the first recess and the second recesses.

15. The method of claim 14, wherein performing the etching process comprises performing a wet etching process using HF as an etchant.

16. The method of claim 14, wherein performing the etching process comprises performing a dry etching process using a mixture of NF₃ and NH₃.

17. The method of claim 14, wherein forming the gate structure comprises:
forming a gate dielectric layer in the first recess and the second recesses; and
forming a gate electrode over the gate dielectric layer in the first recess and the second recesses.

18. The method of claim 14, wherein forming the gate structure comprises:
forming a gate dielectric layer in the first recess and the second recesses, wherein the gate dielectric layer fills the second recesses; and
forming a gate electrode over the gate dielectric layer in the first recess.

19. The method of claim 14, wherein an interface between the second portions of the dummy gate dielectric layer and the gate structure is sloped.

20. The method of claim 14, wherein the dummy gate dielectric layer comprises silicon oxycarbide (SiOC).
